(19) United States
(12) Patent Application Publication
(10) Pub. No.: US 2024/0106193 A1
(43) Pub. Date: Mar. 28, 2024

(54) LIGHT EMITTING COMPONENT, SEMICONDUCTOR-LAMINATED SUBSTRATE, AND MEASUREMENT APPARATUS

(71) Applicants: FUJIFILM Business Innovation Corp., Tokyo (JP); FUJIFILM Corporation, Tokyo (JP)

(72) Inventors: Saori NISHIZAKI, Kanagawa (JP); Takashi KONDO, Kanagawa (JP); Takafumi HIGUCHI, Kanagawa (JP); Junichiro HAYAKAWA, Kanagawa (JP); Daisuke IGUCHI, Kanagawa (JP); Tomoaki SAKITA, Kanagawa (JP); Kei TAKEYAMA, Kanagawa (JP)

(73) Assignees: FUJIFILM Business Innovation Corp., Tokyo (JP); FUJIFILM Corporation, Tokyo (JP)

(21) Appl. No.: 18/301,998

(22) Filed: Apr. 18, 2023

(30) Foreign Application Priority Data
Sep. 27, 2022 (JP) 2022-154165

(51) Int. Cl. H01S 5/04; H01S 5/00; H01S 5/30; H01S 5/42

(52) U.S. Cl. CPC H01S 5/041; H01S 5/0028; H01S 5/3013; H01S 5/423

(57) ABSTRACT

A light emitting component includes: a substrate; a plural light emitting elements that are provided on the substrate and respectively have light emission regions; and a plural thyristors that are turned on to cause the light emission regions of the respective light emitting elements to emit light, or that increase amounts of emitted light of the light emission regions, in which the light emitting elements absorb light emitted from a corresponding thyristor among the plural thyristors.

### CROSS-REFERENCE TO RELATED APPLICATIONS

This application is based on and claims priority under 35 USC 119 from Japanese Patent Application No. 2022-154165 filed Sep. 27, 2022.

### BACKGROUND

### (i) Technical Field

The present invention relates to a light emitting component, a semiconductor-laminated substrate, and a measurement apparatus.

### (ii) Related Art

JP2018-6502 discloses a light emitting component which includes a substrate, a plurality of light emitting elements formed of a vertical cavity surface emitting Laser provided on the substrate, and a setting thyristor laminated on each light emitting element and used to drive the light emitting element. In the light emitting component, in a case where the setting thyristor is turned on, a current flows between the setting thyristor and the light emitting element, and the light emitting element emits light.

### SUMMARY

Meanwhile, the thyristor turned on may emit light. In a light emitting component or the like including a plurality of thyristors, in a case where light emitted from a thyristor that has been turned on propagates to a different thyristor, the propagating light may cause the different thyristor to transition to an ON state. In such a case, the different thyristor that has been turned on may cause the light emitting element that is not intended to emit light to emit light, and it is difficult to control light emission of the light emitting element.

Aspects of non-limiting embodiments of the present disclosure relate to a light emitting component that makes light, which is emitted from a thyristor, unlikely to propagate to a different thyristor, as compared with a case where a light emitting element or a semiconductor laminate processed into a light emitting element does not absorb light emitted from the thyristor.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting component including: a substrate; a plurality of light emitting elements that are provided on the substrate and respectively have light emission regions; and a plurality of thyristors that are turned on to cause the light emission regions of the respective light emitting elements to emit light, or that increase amounts of emitted light of the light emission regions, in which the light emitting elements absorb light emitted from a corresponding thyristor among the plurality of thyristors.

### BRIEF DESCRIPTION OF THE DRAWINGS

Exemplary embodiment(s) of the present invention will be described in detail based on the following figures, wherein:

FIG. 1 is a diagram showing an example of a measurement apparatus according to the present exemplary embodiment;

FIG. 2 is a diagram showing a light source device according to the present exemplary embodiment;

FIGS. 3A and 3B are examples of a plan layout view and a cross-sectional view of a light emitting chip according to the present exemplary embodiment;

FIG. 4 is an enlarged cross-sectional view of an island in which a VCSEL and a setting thyristor are laminated;

FIG. 5 is a timing chart showing operation examples of the light source device and the light emitting chip;

FIG. 6 is a diagram showing an example of the behavior of the light emitted from the setting thyristors in a case where the VCSELs do not absorb the light emitted from the setting thyristors;

FIG. 7 is a diagram showing an example of behavior of light emitted from the setting thyristors in a light emitting chip according to the present exemplary embodiment; and

FIG. 8 is a diagram showing a light emitting chip according to Exemplary Embodiment 2, and is an example of an enlarged cross-sectional view of an island in which a VCSEL and a setting thyristor are laminated.

### DETAILED DESCRIPTION

Hereinafter, exemplary embodiments of the present invention will be described in detail with reference to the accompanying drawings.

Here, a case where the light source device 1 including a light emitting chip 10 which is an example of a light emitting component is applied to a measurement apparatus that measures a three-dimensional shape (hereinafter, referred to as a 3D shape) of a measurement target object is applied as an example.

### Exemplary Embodiment 1

Measurement Apparatus 100

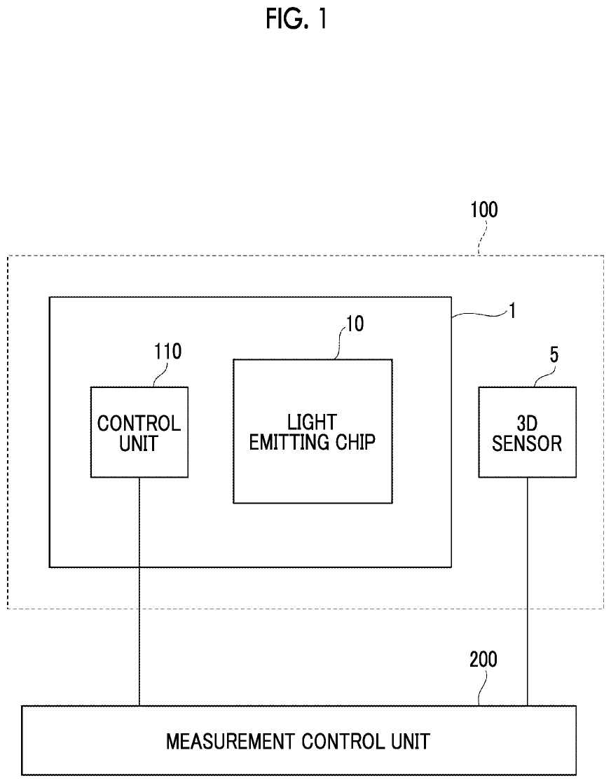

FIG. 1 is a diagram showing an example of a measurement apparatus 100 according to the present exemplary embodiment.

The measurement apparatus 100 of the present exemplary embodiment measures a three-dimensional shape (hereinafter, referred to as a 3D shape) of a measurement target object. The measurement apparatus 100 is an apparatus that measures a 3D shape on the basis of a so-called time-of-flight (ToF) method on the basis of the flight time of light. The measurement apparatus 100 includes a light source device 1 as an example of a light emitting device including a light emitting chip 10 and a control unit 110, and a three-dimensional sensor (hereinafter, referred to as a 3D sensor) 5. In the ToF method, a time from the timing at which light is emitted from the light source device 1 to the timing at which light is reflected by the measurement target object and received by the 3D sensor 5 is measured. Then, a distance to the measurement target object is calculated from the time acquired from the 3D sensor 5, and the 3D shape of the measurement target object is specified. In addition, measuring a 3D shape may be referred to as three-dimensional measurement, 3D measurement, or 3D sensing.

The light source device 1 emits light toward the measurement target object. The 3D sensor 5 acquires the light (reflected light) that has been reflected by the measurement target object and returned. The 3D sensor 5 outputs information (distance information) relating to the distance to the measurement target object, which is measured by the ToF method and is based on the time from the emission to the reception of the reflected light. The measurement apparatus 100 may include a measurement control unit 200. The measurement control unit 200 is configured as a computer including a CPU, a ROM, a RAM, and the like, and specifies the 3D shape of the measurement target object on the basis of the distance information acquired from the 3D sensor 5.

Further, the measurement apparatus 100 can be applied to recognize the measurement target object from the specified 3D shape. For example, the measurement apparatus 100 is mounted on a portable information processing apparatus or the like and is used for recognizing a face of a user who intends to access the apparatus. That is, the information processing apparatus (portable information processing apparatus) is permitted to be used only in a case where the 3D shape of the face of the accessing user is acquired, whether or not the access is permitted is identified, and the user is recognized as the user who is permitted to access the information processing apparatus.

Further, the measurement apparatus 100 can be applied to a case where the 3D shape of the measurement target object is continuously measured, such as augmented reality (AR).

Light Source Device 1

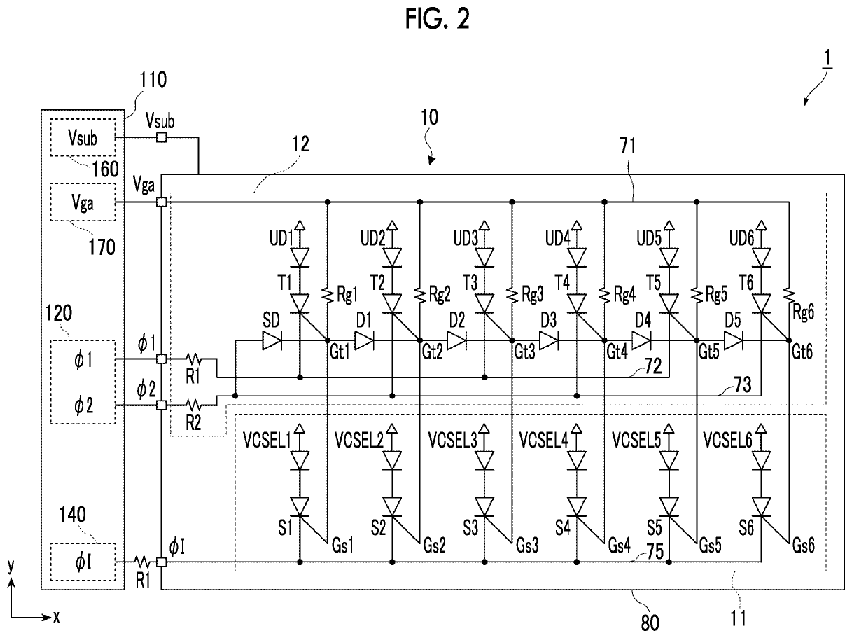

FIG. 2 is a diagram showing a light source device 1 according to the present exemplary embodiment. In FIG. 2, the right direction of the page is defined as the +x direction. In the light source device 1 shown in FIG. 2, the positions of the terminals (φ1 terminal, φ2 terminal, Vga terminal, and φI terminal) are not constantly accurate.

The light source device 1 shown in FIG. 2 includes the light emitting chip 10 and the control unit 110.

Control Unit 110

The control unit 110 includes a transfer signal generating unit 120, a lighting signal generating unit 140, a reference potential supply unit 160, and a power source potential supply unit 170.

The transfer signal generating unit 120 generates the transfer signals φ1 and φ2 that sequentially transfer the ON state to a plurality of transfer thyristors T to be described later. The lighting signal generating unit 140 generates a lighting signal φI that supplies a current for lighting (emitting light of) a plurality of VCSELs, which will be described later. The reference potential supply unit 160 supplies a reference potential Vsub. The power source potential supply unit 170 supplies the power source potential Vga.

Light Emitting Chip 10

The light emitting chip 10 includes a light emitting unit 11 and a transfer unit 12. Further, the light emitting chip 10 includes a φ1 terminal, a φ2 terminal, a Vga terminal, a φI terminal, and a Vsub terminal.

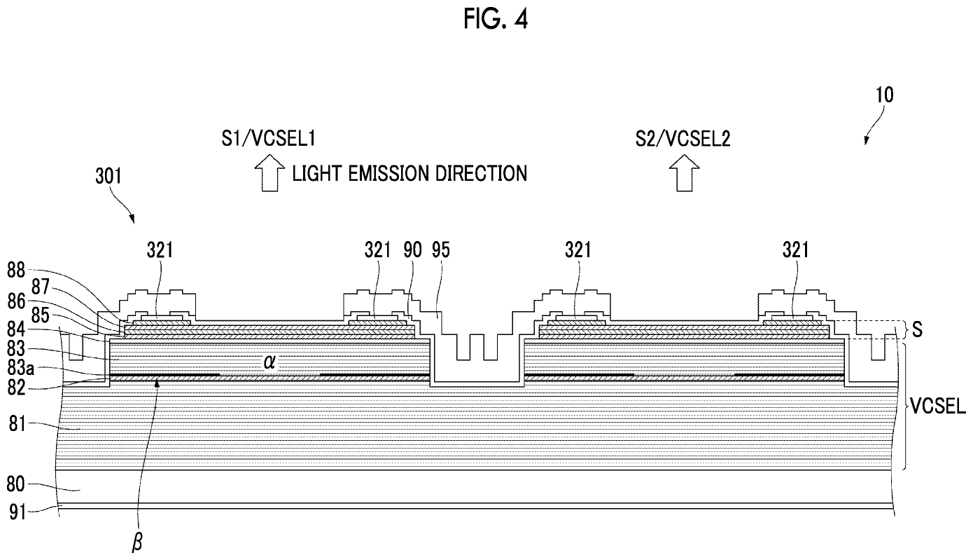

The light emitting unit 11 includes a vertical cavity surface emitting Laser (VCSEL). Hereinafter, the vertical cavity surface emitting Laser VCSEL will be referred to as VCSEL. In the example shown in FIG. 2, six VCSELs of VCSEL1 to VCSEL6 (referred to as the VCSEL in a case where no distinction is made) are provided. Further, the light emitting unit 11 includes six setting thyristors S1 to S6 (referred to as the setting thyristor S in a case where no distinction is made). The anode of the VCSEL and the cathode of the setting thyristor S are connected to each other. That is, the VCSEL and the setting thyristor S having the same number are connected in series. In addition, as shown in FIG. 4 to be described later, the setting thyristors S are laminated on the VCSELs formed on the substrate 80. It should be noted that, in the following description, the setting thyristor S may be referred to as a thyristor.

In the present exemplary embodiment, each VCSEL is an example of the light emitting element. Further, each setting thyristor S is an example of the thyristor.

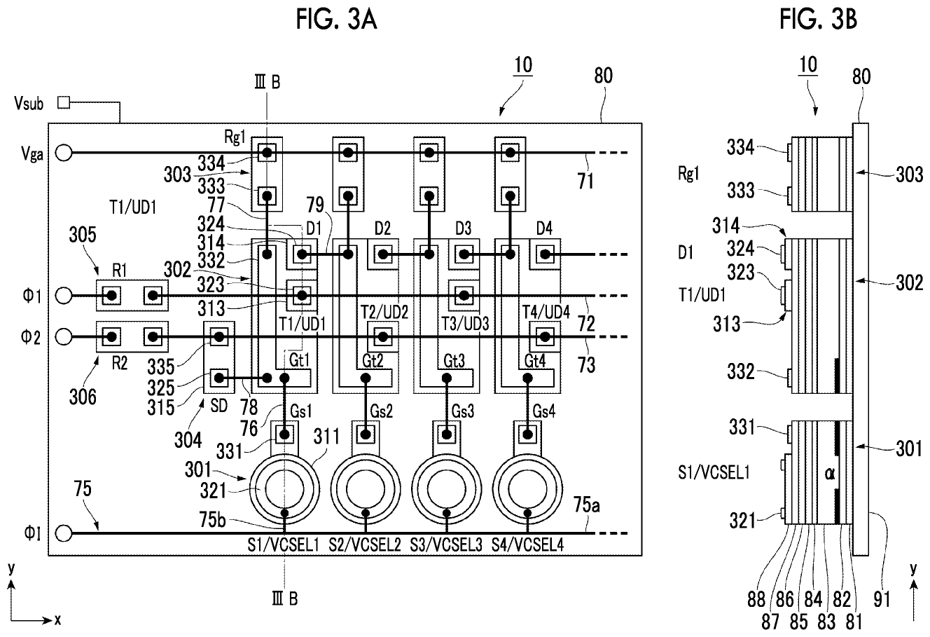

The transfer unit 12 describes the six transfer thyristors T1 to T6 (referred to as the transfer thyristor Tin a case where no distinction is made) and the six lower diodes UD1 to UD6 (referred to as the lower diodes UD in a case where no distinction is made). Then, regarding the transfer thyristors T1 to T6 and the lower diodes UD1 to UD6, the transfer thyristor T and the lower diode UD having the same number are connected in series. In addition, as shown in FIG. 3B to be described later, the transfer thyristor T is laminated on the lower diode UD formed on the substrate 80.

Further, the transfer unit 12 includes pairing two transfer thyristors T1 to T6 in numerical order, and interposing the coupling diodes D1 to D5 (referred to as the coupling diode D in a case where no distinction is made) between the pairs.

Further, the transfer unit 12 includes power source line resistors Rg1 to Rg6 (referred to as the power source line resistor Rg in a case where no distinction is made).

Further, the transfer unit 12 includes one start diode SD.

Furthermore, the transfer unit 12 includes current-limiting resistors R1 and R2 provided to prevent an excessive current from flowing between a first transfer signal line 72 to which the first transfer signal φ1 to be described later is supplied and a second transfer signal line 73 to which the second transfer signal φ2 is supplied.

The VCSEL1 to VCSEL6 of the light emitting unit 11, the setting thyristors S1 to S6, the transfer thyristors T1 to T6 of the transfer unit 12, the lower diodes UD1 to UD6, the coupling diodes D1 to D5, and the power source line resistors Rg1 to Rg6 are arranged in numerical order from one side (the side in the −x direction, the left side in FIG. 2) to the other side (the side in the +x direction, the right side in FIG. 2) in the light emitting chip 10.

In the present exemplary embodiment, each number of the VCSELs and the setting thyristors S in the light emitting unit 11, the transfer thyristors T in the transfer units 12, the lower diodes UD, and the power source line resistors Rg is set to six. It should be noted that the number of coupling diodes D is five, which is smaller by one than the number of transfer thyristors T. Each number of the VCSELs, the setting thyristors S, the transfer thyristors T, the lower diodes UD, the power source line resistors Rg, and the coupling diodes D is not limited to the above, and may be a predetermined number. Further, the number of transfer thyristors T may be greater than the number of VCSELs.

The VCSEL, the lower diode UD, the coupling diode D, and the start diode SD each are a two-terminal semiconductor element including an anode terminal (anode) and a cathode terminal (cathode). Further, the thyristor (the setting thyristor S or the transfer thyristor T) is a three-terminal semiconductor element including an anode terminal (anode), a gate terminal (gate), and a cathode terminal (cathode). It should be noted that, in the following description, the terminals may be abbreviated and indicated in parentheses.

In the light emitting chip 10 of the present exemplary embodiment, the VCSEL, the setting thyristor S, the lower diode UD, the transfer thyristor T, the coupling diode D, the power source line resistor Rg, and the start diode SD each are configured as an integrated circuit by a semiconductor laminate epitaxially grown on a common semiconductor substrate (hereinafter, referred to as a substrate 80). Here, the semiconductor laminate is constituted by a group III-V compound semiconductor such as GaAs, AlGaAs, and AlAs, for example.

Next, electrical connection of each element in the light emitting chip 10 will be described.

Each anode of the VCSEL and the lower diode UD is connected to the substrate 80 (anode common).

The reference potential Vsub is supplied to the anodes through a rear surface electrode 91 which is a Vsub terminal provided on the rear surface of the substrate 80.

Then, each cathode of the VCSEL is connected to the anode of the setting thyristor S. Further, each cathode of the lower diode UD is connected to the anode of the transfer thyristor T.

In addition, the connection is a configuration in a case where the p-type substrate 80 is used. In a case where an n-type substrate is used, the polarities are reversed. In a case where an intrinsic (i) type substrate to which no impurities are added is used, a terminal for supplying the reference potential Vsub is provided on a side of the substrate on which the light emitting unit 11 and the transfer unit 12 are provided.

According to arrangement of the transfer thyristors T, the cathodes of the transfer thyristors T1, T3, and T5 having odd numbers are connected to the first transfer signal line 72. Then, the first transfer signal line 72 is connected to the φ1 terminal with the current-limiting resistor R1 interposed therebetween. A first transfer signal φ1 is supplied to the φ1 terminal from the transfer signal generating unit 120 of the control unit 110.

On the other hand, according to the arrangement of the transfer thyristors T, the cathodes of the even-numbered transfer thyristors T2, T4, and T6 are connected to the second transfer signal line 73. Then, the second transfer signal line 73 is connected to the φ2 terminal with the current-limiting resistor R2 interposed therebetween. A second transfer signal φ2 is supplied to the φ2 terminal from the transfer signal generating unit 120 of the control unit 110.

Each cathode of the setting thyristor S is connected to a lighting signal line 75. The lighting signal line 75 is connected to the φI terminal. In the light emitting chip 10, the φI terminal is supplied with the lighting signal φI from the lighting signal generating unit 140 of the control unit 110 with the current-limiting resistor RI interposed therebetween and provided on the outside of the light emitting chip 10. The lighting signal φI supplies a current for lighting to the VCSEL.

Respective gates Gt1 to Gt6 of the transfer thyristors T1 to T6 (referred to as gates Gt in a case where no distinction is made) are connected one-to-one to gates Gs1 to Gs6 of the setting thyristors S1 to S6 with the same numbers (referred to as gates Gs in a case where no distinction is made). Consequently, the gates Gt1 to Gt6 and the gates Gs1 to Gs6 having the same number have electrically the same potential. Accordingly, for example, the gate Gt1 (gate Gs1) is noted to indicate that the electric potentials are the same.

The coupling diodes D1 to D5 are connected between the gates Gt in which the gates Gt1 to Gt6 of the transfer thyristors T1 to T6 are paired by two in numerical order. That is, the coupling diodes D1 to D5 are directly connected so as to be interposed between the gates Gt1 to Gt6. Then, the direction of the coupling diode D1 is connected in a direction in which a current flows from the gate Gt1 to the gate Gt2. It is the same for the other coupling diodes D2 to D5.

The gate Gt (gate Gs) of the transfer thyristor is connected to a power source line 71 with the power source line resistor Rg interposed therebetween and provided corresponding to each of the transfer thyristors T. The power source line 71 is connected to the Vga terminal. The power source potential Vga is supplied to the Vga terminal from the power source potential supply unit 170 of the control unit 110.

The gate Gt1 of the transfer thyristor T is connected to the cathode of the start diode SD. On the other hand, the anode of the start diode SD is connected to the second transfer signal line 73.

FIGS. 3A and 3B are examples of a plan layout view and a cross-sectional view of the light emitting chip 10 according to the present exemplary embodiment. FIG. 3A is an example of a plan layout view of the light emitting chip 10, and FIG. 3B is an example of a cross-sectional view taken along the line IBB-IIIB of FIG. 3A.

It should be noted that, in FIGS. 3A and 3B, the protective layer (a protective layer 90 of FIG. 4 to be described later) and the light blocking layer (a light blocking layer 95 of FIG. 4 to be described later) to be described later are not shown. Further, in FIG. 3B, each connection wiring shown in FIG. 3A is not shown.

First, a cross-sectional structure of the light emitting chip 10 will be described with reference to FIG. 3B.

In the light emitting chip 10, a p-type anode layer 81, a light emission layer 82, and an n-type cathode layer 83 constituting the VCSEL and the lower diode UD are sequentially provided on the p-type substrate 80 (substrate 80). Although details will be described later, in the light emitting chip 10 of the present exemplary embodiment, the p-type anode layer 81 and the n-type cathode layer 83 are constituted by distributed Bragg reflection layers (DBR: Distributed Bragg Reflector) on which a plurality of semiconductor layers with different refractive indexes are laminated (hereinafter, referred to as DBR layers). Consequently, in the following description, the p-type anode layer 81 will be referred to as a p-anode (DBR) layer 81. In a similar manner, the n-type cathode layer 83 is referred to as an n-cathode (DBR) layer 83.

In the light emitting chip 10, a tunnel junction (tunnel diode) layer 84 (tunnel junction layer 84) is provided on the n-cathode (DBR) layer 83.

Further, in the light emitting chip 10, a p-type anode layer 85 (p-anode layer 85) constituting the setting thyristor S, the transfer thyristor T, the coupling diode D, and the power source line resistor Rg, an n-type gate layer 86 (n-gate layer 86), a p-type gate layer 87 (p-gate layer 87), and an n-type cathode layer 88 (n-cathode layer 88) are provided on the tunnel junction layer 84 in this order.

It should be noted that, in the following description, the notation in parentheses will be used. It is the same for other cases.

Elements such as the VCSEL, the lower diode UD, the setting thyristor S, the transfer thyristor T, and the coupling diode D are constituted of a plurality of islands separated by removing a part of each of the above layers through etching. The island may be referred to as a mesa, and the etching, which forms an island (mesa), may be referred to as a mesa etching.

In the light emitting chip 10, the islands and wirings such as the power source line 71, a first transfer signal line 72, a second transfer signal line 73, and a lighting signal line 75 are connected through a through-hole (indicated by “o” in FIG. 3A) provided in a protective layer (a protective layer 90 of FIG. 4 to be described later). In the following description, the protective layer and the through-hole will not be described.

Further, as shown in FIG. 3B, the rear surface electrode 91 serving as the Vsub terminal is provided on the rear surface of the substrate 80.

Here, the notation of the p-anode (DBR) layer 81 and the n-cathode (DBR) layer 83 corresponds to functions (actions) in a case where the layers constitute the VCSEL and the lower diode UD. That is, the p-anode (DBR) layer 81 functions as an anode, and the n-cathode (DBR) layer 83 functions as a cathode.

Further, the notations of the p-anode layer 85, the n-gate layer 86, the p-gate layer 87, and the n-cathode layer 88 correspond to functions (actions) in a case where the layers constitute the setting thyristor S and the transfer thyristor T. That is, the p-anode layer 85 functions as an anode, the n-gate layer 86 and the p-gate layer 87 function as a gate, and the n-cathode layer 88 functions as a cathode.

In a case where each of the above-mentioned layers constitutes the coupling diode D and the power source line resistor Rg, the layers have different functions as described later.

As described below, the plurality of islands included in the light emitting chip 10 include islands which do not include a part of the layer among the p-anode (DBR) layer 81, the light emission layer 82, the n-cathode (DBR) layer 83, the tunnel junction layer 84, and the p-anode layer 85, the n-gate layer 86, the p-gate layer 87, and the n-cathode layer 88. For example, islands 301 and 302 to be described later do not include a part of the n-cathode layer 88.

Next, an example of the plan layout of the light emitting chip 10 will be described with reference to FIG. 3A.

The island 301 is provided with the VCSEL1 and the setting thyristor S1. The island 302 is provided with the lower diode UD1, the transfer thyristor T1, and the coupling diode D1. The island 303 is provided with the power source line resistor Rg1. The island 304 is provided with the start diode SD. The island 305 is provided with the current-limiting resistor R1, and the island 306 is provided with the current-limiting resistor R2.

The plurality of islands in a similar manner to the islands 301, 302, and 303 are formed in parallel on the light emitting chip 10. The VCSEL2 to VCSEL6, the setting thyristors S2 to S6, the lower diodes UD2 to UD6, the transfer thyristors T2 to T6, the coupling diodes D2 to D5, and the like are provided in the islands in the same manner as the islands 301, 302, and 303.

Here, the islands 301 to 306 will be described in detail with reference to FIGS. 3A and 3B.

As shown in FIG. 3B, the VCSEL1 provided in the island 301 is constituted of the p-anode (DBR) layer 81, the light emission layer 82, and the n-cathode (DBR) layer 83. The setting thyristor S is constituted of the p-anode layer 85, the n-gate layer 86, the p-gate layer 87, and the n-cathode layer 88 which are laminated with the tunnel junction layer 84 interposed therebetween and laminated on the n-cathode (DBR) layer 83 of the VCSEL1.

As shown in the black portions of FIG. 3B, the n-cathode (DBR) layer 83 of the VCSEL includes a current constriction layer (current constriction layer 83a in FIG. 4 to be described later) that constricts the current. The current constriction layer is a current blocking portion β in which a current is unlikely to flow since a part of a semiconductor layer constituting the n-cathode (DBR) layer exposed through mesa etching is oxidized from the outer periphery. On the other hand, a central portion in which a part of the semiconductor layer constituting the n-cathode (DBR) layer is not oxidized is a current passage portion α through which a current is likely to flow. As shown in the VCSEL1 of FIG. 3A, the inside of the broken line is the current passage portion α, and the outside of the broken line is the current blocking portion β. The current blocking portion β to completely block the flow of the current, and may concentrate the current in the current passage portion α. That is, the current blocking portion β may be unlikely to flow a current than the current passage portion α.

By providing the current blocking portion β, power consumed for the non-emission recombination is suppressed. By providing the current blocking portion β, it is possible to reduce power consumption and improve light extraction efficiency. It should be noted that the light extraction efficiency is an amount of light that can be extracted per power.

In the setting thyristor S1, an n-type ohmic electrode 321 (n-ohmic electrode 321), which is provided on a region 311 of the n-cathode layer 88, is used as the cathode terminal. Further, a p-type ohmic electrode 331 (p-ohmic electrode 331), which is provided on the p-gate layer 87 exposed by removing the n-cathode layer 88, is used as a terminal of the gate Gs1.

In a similar manner to the VCSEL, the lower diode UD1 provided in the island 302 is constituted of the p-anode (DBR) layer 81, the light emission layer 82, and the n-cathode (DBR) layer 83. In a similar manner to the setting thyristor S1, the transfer thyristor T1 is constituted of the p-anode layer 85, the n-gate layer 86, and the p-gate layer 87, and the n-cathode layer 88, which are laminated with the tunnel junction layer 84 interposed therebetween and laminated on the n-cathode (DBR) layer 83 of the lower diode UD1.

In addition, an n-ohmic electrode 323, which is provided on a region 313 of the n-cathode layer 88, is set as a cathode terminal. Further, a p-ohmic electrode 332, which is provided on the p-gate layer 87 exposed by removing the n-cathode layer 88, is used as a terminal of the gate Gt1.

In a similar manner, the coupling diode D1, which is provided in the island 302, is constituted of the p-gate layer 87 and the n-cathode layer 88. Further, an n-ohmic electrode 324, which is provided on a region 314 of the n-cathode layer 88, is used as a cathode terminal. Further, the p-ohmic electrode 332, which is provided on the p-gate layer 87 exposed by removing the n-cathode layer 88, is used as an anode terminal. Here, the anode terminal of the coupling diode D is the same as the gate Gt1.

The power source line resistor Rg1, which is provided in the island 303, is constituted by the p-gate layer 87. That is, the power source line resistor Rg1 is provided with the p-gate layer 87 between the p-ohmic electrode 333 and the p-ohmic electrode 334 provided on the A-gate layer 87 exposed by removing the n-cathode layer 88 as a resistor.

The start diode SD, which is provided in the island 304, is constituted of the p-gate layer 87 and the n-cathode layer 88. That is, in the start diode SD, an n-ohmic electrode 325 provided on a region 315 of the n-cathode layer 88 serves as a cathode terminal. Further, a p-ohmic electrode 335, which is provided on the p-gate layer 87 exposed by removing the n-cathode layer 88, is used as an anode terminal.

The current-limiting resistor R1 provided in the island 305 and the current-limiting resistor R2 provided in the island 306 are provided in the same manner as the power source line resistor Rg1 provided in the island 303, and each resistor uses the p-gate layer 87 between the two p-ohmic electrodes (unsigned) as a resistance.

Next, a connection relationship between the elements will be described with reference to FIG. 3A.

The lighting signal line 75 includes a trunk portion 75a and a plurality of branch portions 75b. The trunk portion 75a is provided so as to extend in the row direction of the setting thyristors S/VCSEL. The branch portion 75b is branched from the trunk portion 75a and is connected to the n-ohmic electrode 321 which is a cathode terminal of the setting thyristor S1 provided in the island 301. It is the same for the cathode terminals of the other setting thyristors S.

The lighting signal line 75 is connected to the φI terminal which is provided on the setting thyristor S1/VCSEL1 side.

The first transfer signal line 72 is connected to the n-ohmic electrode 323 as a cathode terminal of the transfer thyristor T1 which is provided in the island 302. The cathode terminal of another transfer thyristor T having an odd number, which is provided on an island similar to the island 302, is connected to the first transfer signal line 72. The first transfer signal line 72 is connected to the φ1 terminal with the current-limiting resistor R1 interposed therebetween and provided in the island 305.

On the other hand, the second transfer signal line 73 is connected to an n-ohmic electrode (unsigned) as a cathode terminal of an even-numbered transfer thyristor T which is provided on an unsigned island. The second transfer signal line 73 is connected to the φ2 terminal with the current-limiting resistor R2 interposed therebetween and provided in the island 306.

The power source line 71 is connected to the p-ohmic electrode 334 as one terminal of the power source line resistor Rg1 which is provided in the island 303. One terminal of another power source line resistor Rg is also connected to the power source line 71. The power source line 71 is connected to the Vga terminal.

The p-ohmic electrode 331 (gate terminal Gs1) of the setting thyristor S1, which is provided in the island 301, is connected to the p-ohmic electrode 332 (gate terminal Gt1) of the island 302 through a connection wiring 76.

The p-ohmic electrode 332 (gate terminal Gt1) is connected to the p-ohmic electrode 333 (the other terminal of the power source line resistor Rg1) of the island 303 through a connection wiring 77.

The n-ohmic electrode 324 (cathode terminal of the coupling diode D1), which is provided in the island 302, is connected to a p-type ohmic electrode (unsigned) as the gate terminal Gt2 of the adjacent transfer thyristor T2 through a connection wiring 79.

Although description is not given here, it is the same for other VCSELs, the setting thyristor S, the transfer thyristor T, the coupling diode D, and the like.

The p-ohmic electrode 332 (gate terminal Gt1) of the island 302 is connected to the n-ohmic electrode 325 (cathode terminal of the start diode SD) provided in the island 304 through a connection wiring 78. The p-ohmic electrode 335 (the anode terminal of the start diode SD) is connected to the second transfer signal line 73.

It should be noted that the above-mentioned connection and configuration are for a case of using the p-type substrate 80, and the polarities thereof are opposite to each other in a case of using the n-type substrate. Further, in a case of using an i-type substrate, a terminal for supplying the reference potential Vsub is provided on a side of the substrate on which the light emitting unit 11 and the transfer unit 12 are provided. In addition, the connection and configuration are the same as either in the case of using the p-type substrate or in the case of using the n-type substrate.

Laminated Structure of VCSEL and Setting Thyristor S

FIG. 4 is an example of an enlarged cross-sectional view of the island in which the VCSEL and the setting thyristor S are laminated. It should be noted that FIG. 4 corresponds to a view of a cross unit of the island in which the VCSEL and the setting thyristor S are laminated, as viewed from a −y direction. Further, FIG. 4 shows the island 301 in which the VCSEL1 and the setting thyristor S1 are laminated, and the island (unsigned) in which the VCSEL2 and the setting thyristor S2 are laminated. In FIG. 4, the VCSEL1 and the VCSEL2 are not distinguished and are referred to as the VCSEL. In a similar manner, the setting thyristor S1 and the setting thyristor S2 are not distinguished and are referred to as the setting thyristor S.

As described above, the setting thyristor S is laminated on the VCSEL with the tunnel junction layer 84 interposed therebetween. That is, the VCSEL and the setting thyristor S are connected in series.

The term “on the VCSEL” does not mean only a state of being in direct contact with the VCSEL, but also includes a state of being positioned above without direct contact. It is the same for similar expressions such as “on the substrate”.

As shown in FIG. 4, the VCSEL is constituted by a semiconductor laminate in which the p-anode (DBR) layer 81, the light emission layer 82, and the n-cathode (DBR) layer 83 are epitaxially grown on the p-type substrate 80 in order.

The p-anode (DBR) layer 81 and the n-cathode (DBR) layer 83 are DBR layers in which a plurality of high refractive index layers each having a relatively high refractive index and a plurality of low refractive index layers each having a relatively low refractive index are alternately laminated. Then, the p-anode (DBR) layer 81 and the n-cathode (DBR) layer 83 are configured to reflect the light emitted by the VCSEL. It should be noted that the p-anode (DBR) layer 81 and the n-cathode (DBR) layer 83 will be described in more detail later.

Further, the n-cathode (DBR) layer 83 is configured to include the current constriction layer 83a. In the present example, the current constriction layer 83a is provided on a side of the n-cathode (DBR) layer 83 facing the light emission layer 82. The current constriction layer 83a is constituted of the current passage portion α and the current blocking portion β. As shown in FIG. 4, the current passage portion α is provided in the central portion of the VCSEL, and the current blocking portion β is provided in the peripheral portion of the VCSEL. That is, a portion of the current constriction layer 83a is the current blocking portion β, and a portion where the current constriction layer 83a is not provided is the current passage portion α.

It should be noted that the current constriction layer may be provided on the p-anode (DBR) layer 81.

The light emission layer 82 is a quantum well structure, in which well layers and barrier layers are alternately laminated. The light emission layer 82 may be an intrinsic (i) type layer (i layer), to which no impurities are added. In addition, the light emission layer 82 may have a structure other than the quantum well structure, and may be, for example, a quantum ray (quantum wire) or a quantum box (quantum dot).

The tunnel junction layer 84 has a junction between an n⁺⁺ layer to which n-type impurities (dopant) are added at a high concentration and a p⁺⁺ layer to which p-type impurities are added at a high concentration. Through the junction, current flows due to the tunnel effect even in reverse bias. The tunnel junction layer 84 suppresses a case where the n-cathode (DBR) layer 83 of the VCSEL and the setting thyristor S have a reverse bias and the current is unlikely to flow. Even with the reverse bias, current flows due to the tunnel effect.

The setting thyristor S is constituted of the p-anode layer 85, the n-gate layer 86, the A-gate layer 87, and the n-cathode layer 88 laminated on the tunnel junction layer 84. That is, the structure thereof is a four-layer structure of pnpn.

The semiconductor layers each are, for example, a semiconductor laminate which is formed by lamination using a metal organic chemical vapor deposition (MOCVD) method, a molecular beam epitaxy (MBE) method, or the like.

Configurations of the substrate 80, the p-anode (DBR) layer 81 that constitutes the VCSEL, the light emission layer 82, the n-cathode (DBR) layer 83, the p-anode layer 85 that constitutes the setting thyristor S, the n-gate layer 86, and the p-gate layer 87, and the n-cathode layer 88 will be described in more detail later.

The n-ohmic electrode 321 is an Au (AuGe) or the like including Ge that is likely to make ohmic contact with an n-type semiconductor layer such as the n-cathode layer 88.

The p-ohmic electrode 331 (refer to FIG. 3B) is, for example, Au (AuZn) including Zn that is likely to make ohmic contact with a p-type semiconductor layer such as the p-gate layer 87.

The rear surface electrode 91 is, for example, AuZn, similarly to the p-ohmic electrode 331.

In the above-mentioned description, the p-gate layer 87 is provided with the ohmic electrode 331 to provide the gate Gs of the setting thyristor S. However, the n-gate layer 86 may be provided with the n-ohmic electrode to provide the gate Gs of the setting thyristor S.

Further, the light emitting chip 10 is provided with the protective layer 90 constituted of a translucent insulating material provided to cover the front surface and the side surface of the island. The protective layer 90 is formed of, for example, SiO₂, SiON, SiN, or the like.

Further, the light emitting chip 10 is provided with the light blocking layer 95 for suppressing leakage of light or the like emitted from the setting thyristor S from a part between the islands to the front surface of the light emitting chip 10. The light blocking layer 95 may be the above-mentioned wiring.

Relationship Between Adjacent Setting Thyristor S and VCSEL

As described above, in the light emitting chip 10 of the present exemplary embodiment, each island is formed by removing a part of the semiconductor layers laminated on the substrate 80 in the thickness direction through mesa etching. For example, in an island (island 301) in which the VCSEL and the setting thyristor S are laminated, among the semiconductor layers laminated on the substrate 80, in order from the upper side, the n-cathode layer 88, the p-gate layer 87, the n-gate layer 86, the p-anode layer 85, the tunnel junction layer 84, the n-cathode (DBR) layer 83, and the light emission layer 82 are removed, and a part of the p-anode (DBR) layer 81 is removed.

Thereby, each setting thyristor S is constituted of the p-anode layer 85, the n-gate layer 86, the p-gate layer 87, and the n-cathode layer 88 that are separated from the adjacent setting thyristor S. In other words, the p-anode layer 85, the n-gate layer 86, the p-gate layer 87, and the n-cathode layer 88 constituting each setting thyristor S are not continuous with the adjacent setting thyristor S.

On the other hand, in the VCSELs of the present exemplary embodiment, a semiconductor layer constituting the VCSEL (for example, VCSEL1) corresponding to a thyristor S (for example, thyristor S1) among a plurality of thyristors S is continuous with at least a part of a semiconductor layer constituting the VCSEL (for example, VCSEL2) corresponding to a different adjacent thyristor S (for example, thyristor S2). The semiconductor layer constituting the VCSEL corresponding to the thyristor S is an example of the first region, and the semiconductor layer constituting the VCSEL corresponding to the different thyristor S is an example of the second region.

Specifically, in the VCSELs of the present exemplary embodiment, a part of the p-anode (DBR) layer 81, which is the lowest layer, is continuous between the adjacent VCSELs. In the VCSELs, the light emission layer 82 and the n-cathode (DBR) layer 83 laminated on the p-anode (DBR) layer 81 are not continuous with the adjacent VCSELs.

Further, the VCSEL of the present exemplary embodiment includes the p-anode (DBR) layer 81 which is an example of the lower semiconductor layer which is laminated on the substrate 80 and is continuous over the adjacent VCSEL1 and VCSEL2. Furthermore, the VCSEL of the present exemplary embodiment includes the n-cathode (DBR) layer 83 which is an example of the upper semiconductor layer that is separated between the adjacent VCSEL1 and the VCSEL2.

Thyristor

Subsequently, a basic operation of the thyristor (the transfer thyristor T or the setting thyristor S) will be described. As described above, the thyristor is a semiconductor element having three terminals of an anode terminal (anode), a cathode terminal (cathode), and a gate terminal (gate). For example, p-type semiconductor layers (the p-anode layer 85 and the p-gate layer 87) each constituted of GaAs, AlGaAs, AlAs, or the like and n-type semiconductor layers (the n-gate layer 86 and the n-cathode layer 88) are laminated on the substrate 80. That is, the thyristor has a pnpn structure. Here, a forward electric potential (diffusion electric potential) Vd of a pn junction constituted of the p-type semiconductor layer and the n-type semiconductor layer will be described as 1.5 V as an example.

The following description will be given, for example, under the following assumptions. The reference potential Vsub supplied to the rear surface electrode 91 (refer to FIGS. 3B and 4) which is a Vsub terminal is set to 0 V as a high-level potential (hereinafter referred to as “H”). The power source potential Vga supplied to the Vga terminal is set to −5 V as a low-level potential (hereinafter referred to as “L”). Accordingly, the electric potentials may be noted as “H” (0 V) or “L” (−5 V).

First, an operation of a single thyristor will be described. Here, the anode of the thyristor is set to 0 V.

The thyristor in an OFF state in which no current flows between an anode and the cathode transitions to an ON state (turns on) in a case where an electric potential lower than a threshold voltage (a negative electric potential having a large absolute value) is applied to the cathode. Here, a threshold voltage of the thyristor is a value obtained by subtracting the forward electric potential Vd (1.5 V) of the pn junction from the electric potential of the gate.

In the ON state, the gate of the thyristor has an electric potential close to an electric potential of the anode terminal. Here, since the anode is set to 0 V, the gate is supposed to be 0 V. Further, the cathode of the thyristor in the ON state has an electric potential close to an electric potential obtained by subtracting the forward electric potential Vd (1.5 V) of the pn junction from an electric potential of the anode. Here, since the anode is set to 0 V, the cathode of the thyristor in the ON state has an electric potential close to −1.5 V (a negative electric potential having an absolute value greater than 1.5 V). It should be noted that the electric potential of the cathode is set in relation to the power source that supplies a current to the thyristor in the ON state.

In a case where the cathode of the thyristor in the ON state is set to an electric potential (a negative electric potential with a small absolute value, 0 V, or a positive electric potential) higher than the electric potential (an electric potential close to −1.5 V described above) required to maintain the ON state, the thyristor transitions (is turned off) to the OFF state.

In contrast, in a case where an electric potential lower than the electric potential required to maintain the ON state (a negative electric potential with a large absolute value) is continuously applied to the cathode of the thyristor in the ON state and a current capable of maintaining the ON state (maintenance current) is supplied, the thyristor maintains the ON state.

Next, an operation thereof in a state where the VCSEL and the setting thyristor S are laminated will be described.

The setting thyristor S and the VCSEL are laminated and connected in series.

Accordingly, an electric potential of the lighting signal φI is divided between the VCSEL and the setting thyristor S. Here, description will be given under an assumption that the voltage applied to the VCSEL is −1.7 V. Then, in a case where the setting thyristor S is in the OFF state, −3.3 V is applied to the setting thyristor S.

As described above, in a case where an absolute value of the threshold voltage of the setting thyristor S in the OFF state is greater than an absolute value of −3.3 V, the electric potential applied to the cathode of the setting thyristor S is lower than the threshold voltage. Thus, the setting thyristor S is turned on. Then, the current flows through the VCSEL and the setting thyristor S connected in series, and the VCSEL emits light. In contrast, in a case where the absolute value of the threshold voltage of the setting thyristor S is smaller than the absolute value of −3.3 V, the setting thyristor S is not turned on and maintains the OFF state.

It should be noted that in a case where the setting thyristor S is turned on, the current-limiting resistor RI (refer to FIG. 2) lowers an absolute value of the voltage applied to the VCSEL and the setting thyristor S connected in series. However, in a case where the voltage applied to the setting thyristor S is a voltage which maintains the ON state of the setting thyristor S, the setting thyristor S maintains the ON state. Thereby, the VCSEL also continues to emit light.

It should be noted that the voltage shown above is an example and may be changed in accordance with the emission wavelength and the amount of light of the VCSEL. In such a case, the electric potential (“L”) of the lighting signal φI may be adjusted.

Operation of Light Source Device 1

Timing Chart

Subsequently, an operation of the light source device 1 will be described.

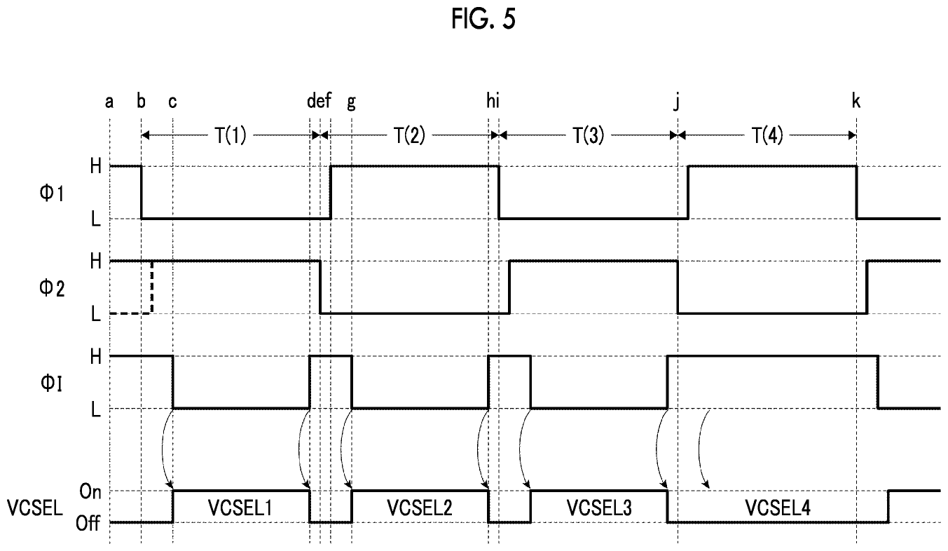

FIG. 5 is a timing chart showing operation examples of the light source device 1 and the light emitting chip 10. FIG. 5 is a timing chart of a portion of the light emitting chip 10 for controlling lighting (light emission)/non-lighting (non-light emission) of the four VCSELs of VCSEL1 to VCSEL4. In FIG. 5, the VCSEL1, the VCSEL2, and the VCSEL3 are set to emit light, and the VCSEL4 is set to emit light.

In FIG. 5, it is assumed that the time elapses from a time a to a time k in alphabetical order. The VCSEL1 is subjected to control of lighting or non-lighting (referred to as lighting control) in a period T(1), the VCSEL2 is subjected to control of lighting or non-lighting in a period T(2), the VCSEL3 is subjected to control of lighting or non-lighting in a period T(3), and the VCSEL4 is subjected to control of lighting or non-lighting in a period T(4).

Here, the periods T(1), T(2), T(3), . . . are defined as periods having the same length, and are referred to as period T in a case where the periods are not distinguished from each other.

The first transfer signal φ1 transmitted to the φ1 terminal (refer to FIGS. 2 and 3) and the second transfer signal φ2 transmitted to the φ2 terminal (refer to FIGS. 2 and 3) are signals having two potentials including “H” (0 V) and “L” (−5 V). In addition, waveforms of the first transfer signal φ1 and the second transfer signal φ2 are repeated with two consecutive periods T (for example, period T(1) and period T(2)) as units.

In the following description, “H” (0 V) and “L” (−5 V) may be abbreviated as “H” and “L”.

The first transfer signal φ1 transitions from “H” (0 V) to “L” (−5 V) at a start time b in the period T(1), and transitions from “L” to “H” at a time f. Then, at an end time i in the period T(2), the transition from “H” to “L” occurs.

The second transfer signal φ2 is “H” (0 V) at the start time b in the period T(1), and transitions from “H” (0 V) to “L” (−5 V) at a time e. Then, transition from “L” to “H” occurs at the end time i in the period T(2).

Comparing the first transfer signal φ1 and the second transfer signal φ2, the second transfer signal φ2 corresponds to a signal obtained by shifting back the first transfer signal φ1 by the period T on the time axis. In contrast, a waveform of the second transfer signal φ2 indicated by the broken line in the period T(1) and a waveform thereof in the period T(2) are repeated in the period T(3) and thereafter. The waveform of the second transfer signal φ2 in the period T(1) is different from the waveform thereof in the period T(3) and thereafter. The reason for this is that the period T(1) is a period during which the light source device 1 starts an operation.

As described later, a pair of transfer signals including the first transfer signal φ1 and the second transfer signal φ2 propagates the ON states of the transfer thyristor T in numerical order, thereby specifying the VCSEL, which has the same number as the transfer thyristor T in the ON state, as a target of lighting or non-lighting (lighting control).

Next, the lighting signal φI supplied to the φI terminal (refer to FIGS. 2 and 3) will be described. The lighting signal φI is a signal having two potentials including “H” (0 V) and “L” (−5 V).

Here, the lighting signal φI will be described in the period T(1) of the lighting control for the VCSEL1. The lighting signal φI is at “H” (0 V) at the start time b in the period T(1), and transitions from “H” (0 V) to “L” (−5 V) at a time c. Then, transition from “L” to “H” occurs at a time d, and “H” is maintained at the time e.

Operations of the light source device 1 and the light emitting chip 10 will be described in accordance with the timing chart shown in FIG. 5, with reference to FIG. 2. In the following description, the periods T(1) and T(2) for the lighting control of the VCSEL1 and the VCSEL2 will be described.

(1) Time a

At the time a, the reference potential supply unit 160 of the control unit 110 of the light source device 1 sets the reference potential Vsub to “H” (0 V). The power source potential supply unit 170 of the control unit 110 sets the power source potential Vga to “L” (−5 V). The transfer signal generating unit 120 of the control unit 110 sets each of the first transfer signal φ1 and the second transfer signal φ2 to “H” (0 V). Thereby, the φ1 terminal and the φ2 terminal of the light emitting chip 10 are changed to “H”. The electric potential of the first transfer signal line 72 connected to the φ1 terminal with the current-limiting resistor R1 interposed therebetween is also “H”, and the second transfer signal line 73 connected to the φ2 terminal with the current-limiting resistor R2 interposed therebetween is also at “H” (refer to FIG. 2).

Then, the lighting signal generating unit 140 of the control unit 110 sets the lighting signal φI to “H” (0 V). Thereby, the φI terminal of the light emitting chip 10 is changed to “H” through the current-limiting resistor RI, and the lighting signal line 75 connected to the φI terminal is also at “H” (0 V).

The anode (p-anode layer 85) of the setting thyristor S is connected to the cathode (n-cathode (DBR) layer 83) of the VCSEL with the tunnel junction layer 84 interposed therebetween, and the anode of the VCSEL (p-anode (DBR) layer 81) is connected to the Vsub terminal which is set to “H”.

The anode (p-anode layer 85) of the transfer thyristor T is connected to the cathode (n-cathode (DBR) layer 83) of the lower diode UD with the tunnel junction layer 84 interposed therebetween, and the anode of the lower diode UD (p-anode (DBR) layer 81) is connected to the Vsub terminal which is set to “H”.

Each cathode of the respective transfer thyristors T1, T3, and T5 having an odd number is connected to the first transfer signal line 72 and is set to “H” (0 V). Each cathode of the transfer thyristors T2, T4, and T6 having an even number is connected to the second transfer signal line 73 and is set to “H”. Accordingly, both the anode and the cathode of the transfer thyristor T are changed to “H”, and the setting thyristor S is in the OFF state. Further, both the anode and the cathode of the lower diode UD are changed to “H” and the lower diode UD is also in the OFF state.

The cathode terminal of the setting thyristor S is connected to the lighting signal line 75 of “H” (0 V). Accordingly, both the anode and the cathode of the transfer thyristor T are changed to “H”, and the setting thyristor S is in the OFF state. Further, both the anode and the cathode of the VCSEL are set to “H” and the VCSEL is in the OFF state.

As described above, the gate Gt1 is connected to the cathode of the start diode SD. The gate Gt1 is connected to the power source line 71 having a power source potential Vga (“L” (−5 V)) with a power source line resistor Rg1 interposed therebetween. Then, the anode terminal of the start diode SD is connected to the second transfer signal line 73 and is connected to the φ2 terminal of “H” (0 V) with the current-limiting resistor R2 interposed therebetween. Accordingly, the start diode SD is forward biased, and the cathode (gate Gt1) of the start diode SD is changed to a value (−1.5 V) which is obtained by subtracting a forward electric potential Vd (1.5 V) of the pn junction from the electric potential (“H” (0 V)) of the anode of the start diode SD. Further, in a case where the gate Gt1 is changed to −1.5 V, the coupling diode D1 is forward biased since the anode (gate Gt1) of the coupling diode D1 is −1.5 V and the cathode is connected to the power source line 71 (“L” (−5 V)) with the power source line resistor Rg2 interposed therebetween. Accordingly, the electric potential of the gate Gt2 is −3 V obtained by subtracting the forward electric potential Vd (1.5 V) of the pn junction from the electric potential (−1.5 V) of the gate Gt1. Further, the coupling diode D2 is forward biased since the anode (gate Gt1) is −3 V and the cathode is connected to the power source line 71 (“L” (−5 V)) with the power source line resistor Rg2 interposed therebetween. Accordingly, the electric potential of the gate Gt3 is −4.5 V obtained by subtracting the forward electric potential Vd (1.5 V) of the pn junction from the electric potential (−3 V) of the gate Gt2. However, the gate Gt of which the number is 4 or more is not affected by the fact that the anode of the start diode SD is at “H” (0 V), and the electric potential of these gate Gt is changed to “L” (−5 V) which is the electric potential of the power source line 71.

It should be noted that since the gate Gt is the gate Gs, the electric potential of the gate Gs is the same as the electric potential of the gate Gt. Accordingly, the threshold voltage of the transfer thyristor T and the setting thyristor S is a value obtained by subtracting the forward electric potential Vd (1.5 V) of the pn junction from the electric potentials of the gates Gt and Gs. That is, the threshold voltages of the transfer thyristor T1 and the setting thyristor S1 are −3 V, the threshold voltages of the transfer thyristor T2 and the setting thyristor S2 are −4.5 V, the threshold voltages of the transfer thyristor T3 and the setting thyristor S3 are −6 V, and the threshold voltages of the transfer thyristors T and the setting thyristors S of which the numbers are 4 or more are −6.5 V.

(2) Time b

At the time b shown in FIG. 5, the first transfer signal φ1 transitions from “H” (0 V) to “L” (−5 V). Thereby, the light source device 1 starts an operation.

In a case where the first transfer signal φ1 transitions from “H” to “L”, the electric potential of the first transfer signal line 72 transitions from “H” (0 V) to “L” (−) through the φ1 terminal and the current-limiting resistor R1. 5 V). Then, since the voltage applied to the transfer thyristor T1 is −3.3 V, the transfer thyristor T1 having the threshold voltage of −3 V is turned on. In such a case, a current flows through the lower diode UD1, such that the transition from the OFF state to the ON state occurs. By turning on the transfer thyristor T1, the electric potential of the first transfer signal line 72 is changed to an electric potential close to −3.2 V (a negative electric potential whose absolute value is greater than 3.2 V), which is obtained by subtracting the forward electric potential Vd (1.5 V) of the pn junction from the electric potential (−1.7 V which is the electric potential applied to the lower diode UD1) of the anode of the transfer thyristor T1.

It should be noted that the transfer thyristor T3 has a threshold voltage of −6 V, and the transfer thyristor T5 has a threshold voltage of −6.5 V. The voltage applied to the transfer thyristor T3 and the transfer thyristor T5 is −1.5 V obtained by adding the voltage 1.7 V applied to the VCSEL to −3.2 V. Therefore, the transfer thyristor T3 and the transfer thyristor T5 are not turned on.

On the other hand, the transfer thyristor T having an even number cannot be turned on since the second transfer signal φ2 is “H” (0 V) and the second transfer signal line 73 is at “H” (0 V).

In a case where the transfer thyristor T1 is turned on, the electric potential of the gate Gt1/Gs1 is changed to “H” (0 V) which is the electric potential of the anode of the transfer thyristor T1. Then, the electric potential of the gate Gt2 (gate Gs2) is −1.5 V, the electric potential of the gate Gt3 (gate Gs3) is −3 V, the electric potential of the gate Gt4 (gate Gs4) is −4.5 V, and the electric potential of the gate Gt (the gate G1) of which the number is 5 or more is changed to “L”.

Thereby, the threshold voltages of the setting thyristor S1 are changed to −1.5 V, the threshold voltages of the transfer thyristor T2 and the setting thyristor S2 are changed to −3 V, the threshold voltages of the transfer thyristor T3 and the setting thyristor S3 are changed to −4.5 V, and the threshold voltages of the transfer thyristor T4 and the setting thyristors S4 are changed to −6 V, and the threshold voltages of the transfer thyristors T5 and T6 and the setting thyristors S5 and S6 are changed to −6.5 V.

However, the first transfer signal line 72 is set to −1.5 V by the transfer thyristor T1 in the ON state. Therefore, the transfer thyristor T having an odd number in the OFF state is not turned on. The second transfer signal line 73 is at “H” (0 V). Therefore, the transfer thyristor T having an even number is not turned on. The lighting signal line 75 is at “H” (0 V). Therefore, none of the VCSELs are lit.

Immediately after the time b (here, in a state in which a thyristor or the like changes due to a change in the electric potential of the signal at the time b and then enters a steady state), the transfer thyristor T1 and the lower diode UD1 are in the ON state, and the other transfer thyristor T, the lower diode UD, the setting thyristor S, and the VCSEL are in the OFF state.

(3) Time c

At the time c, the lighting signal φI transitions from “H” (0 V) to “L” (−5 V).

In a case where the lighting signal φI transitions from “H” to “L”, the lighting signal line 75 transitions from “H” (0 V) to “L” (−5 V) through the current-limiting resistor RI and the φI terminal. Then, 3.3 V, which is the sum of the voltage applied to the VCSEL of 1.7 V, is applied to the setting thyristor S1, the setting thyristor S1 having a threshold voltage of −1.5 V is turned on, and the VCSEL1 is lit (emits light). Thereby, the electric potential of the lighting signal line 75 is changed to an electric potential close to −3.2 V. In addition, the threshold voltage of the setting thyristor S2 is −3 V. However, the voltage applied to the setting thyristor S2 is −1.5 V obtained by adding the voltage of 1.7 V applied to the VCSEL to −3.2 V. As a result, the setting thyristor S2 is not turned on.

Immediately after the time c, the transfer thyristor T 1, the lower diode UD1, and the setting thyristor S1 are in the ON state, and the VCSEL1 is lit (emits light).

(4) Time d

At the time d, the lighting signal φI transitions from “L” (−5 V) to “H” (0 V).

In a case where the lighting signal φI transitions from “L” to “H”, the electric potential of the lighting signal line 75 transitions from −3.2 V to “H” (0 V) through the current-limiting resistor RI and the φI terminal. Then, both the cathode of the setting thyristor S1 and the anode of the VCSEL1 are changed to “H”. Therefore, the setting thyristor S1 is turned off and the VCSEL1 is lit off (is turned off). The lighting period of the VCSEL1 is a period, in which the lighting signal φI is “L”, from the time c at which the lighting signal φI transitions from “H” to “L” to the time d at which the lighting signal φI transitions from “L” to “H”.

Immediately after the time d, the transfer thyristor T1 is in the ON state.

(5) Time e

At the time e, the second transfer signal φ2 transitions from “H” (0 V) to “L” (−5 V). Here, the period T(1) for controlling lighting of the VCSEL1 ends, and the period T(2) for controlling lighting of the VCSEL2 starts.

In a case where the second transfer signal φ2 transitions from “H” to “L”, the electric potential of the second transfer signal line 73 transitions from “H” to “L” through the φ2 terminal. As described above, the transfer thyristor T2 is turned on since the threshold voltage is changed to −3 V. In such a case, a current also flows through the lower diode UD2, such that the transition from the OFF state to the ON state occurs.

Thereby, the electric potential of the gate terminal Gt2 (gate terminal Gs2) is changed to “H” (0 V), the electric potential of the gate Gt3 (gate Gs3) is changed to −1.5 V, the electric potential of the gate Gt4 (gate Gs4) is changed to −3 V, the electric potential of the gate Gt5 (gate Gs5) is changed to −4.5 V, and the electric potential of the gate Gt6 (gate Gs6) is changed to −5 V.

Immediately after the time e, the transfer thyristors T1 and T2 and the lower diodes UD1 and UD2 are in the ON state.

(6) Time f

At the time f, the first transfer signal φ1 transitions from “L” (−5 V) to “H” (0 V).

In a case where the first transfer signal φ1 transitions from “L” to “H”, the electric potential of the first transfer signal line 72 transitions from “L” to “H” through the φ1 terminal. Then, both the anode and the cathode of the transfer thyristor T1 are changed to “H”, such that the transfer thyristor T1 in the ON state is turned off. In such a case, both the anode and the cathode of the lower diode UD1 are also changed to “H”, such that the transition from the ON state to the OFF state occurs.

Then, the electric potential of the gate Gt1 (gate Gs1) changes toward the power source potential Vga (“L” (−5 V)) of the power source line 71 through the power source line resistor Rg1. Thereby, the coupling diode D1 is in a state in which an electric potential is applied in a direction in which a current does not flow (reverse bias). Accordingly, the gate Gt1 (gate Gs1) does not have the effect that the gate Gt2 (gate Gs2) is “H” (0 V). That is, the threshold voltage of the transfer thyristor T having the gate Gt connected by the reverse bias coupling diode D is changed to −6.5 V, and the transfer thyristor T is not turned on even in a case where the first transfer signal φ1 or the second transfer signal φ2 is changed to “L” (−5 V).

Immediately after the time f, the transfer thyristor T2 and the lower diode UD2 are in the ON state.

(7) Others

At the time g, in a case where the lighting signal φI transitions from “H” (0 V) to “L” (−5 V), the setting thyristor S2 is turned on and the VCSEL2 is lit (emits light) in the same manner as the VCSEL1 and the setting thyristor S1 at the time c.

Then, in a case where the lighting signal φI transitions from “L” (−5 V) to “H” (0 V) at the time h, the setting thyristor S2 is turned off in the same manner as the VCSEL1 and the setting thyristor S1 at the time d, and the VCSEL2 is lit off.

Further, in a case where the first transfer signal φ1 transitions from “H” (0 V) to “L” (−5 V) at the time i, the transfer thyristor T3 having a threshold voltage of −3 V is turned on in the same manner as the transfer thyristor T1 at the time b or the transfer thyristor T2 at the time e. At the time point i, the period T(2) for controlling the lighting of the VCSEL 2 ends, and the period T(3) for controlling the lighting of the VCSEL 3 starts.

Thereafter, the above-mentioned process will be repeated.

In a case where the VCSELs are not turned on (do not emit light) but remain lit off (non-lit), similarly to the lighting signal φI shown in a range from the time j to the time kin the period T(4) for controlling the lighting of the VCSEL 4 in FIG. 5, the lighting signal φI may remain at “H” (0 V). By doing so, even in a case where the threshold voltage of the setting thyristor S4 is −1.5 V, the setting thyristor S4 is not turned on and the VCSEL remains lit off (non-lit).

As described above, the gate terminals Gt of the transfer thyristors T are connected to each other through the coupling diode D. Accordingly, in a case where the electric potential of the gate Gt changes, the electric potential of the gate Gs connected to the gate Gt of which the electric potential is changed through the forward bias coupling diode D changes. Then, the threshold voltage of the transfer thyristor T having the gate from which the electric potential is changed changes. In a case where the threshold voltage of the transfer thyristor T is higher than ˜3.3 V (a negative value with a small absolute value), the transfer thyristor T is turned on at a timing at which the first transfer signal φ1 or the second transfer signal φ2 transitions from “H” (0 V) to “L” (−5 V).

Then, the threshold voltage of the setting thyristor S in which the gate Gs is connected to the gate Gt of the transfer thyristor T in the ON state has a threshold voltage of −1.5 V. Therefore, in a case where the lighting signal φI transitions from “H” (0 V) to “L” (−5 V), the transfer thyristor T is turned on, and the VCSEL connected in series to the setting thyristor S is turned on (emits light).

That is, the transfer thyristor T is turned on to specify the VCSEL to be subjected to the lighting control, and the lighting signal φI of “L” (−5 V) turns on the setting thyristor S, which is connected in series to the VCSEL to be subjected to the lighting control, and lights the VCSEL. That is, in the light emitting chip 10, the VCSELs are sequentially turned on by transferring the ON state of the transfer thyristors T.

It should be noted that the lighting signal φI of “H” (0 V) maintains the setting thyristor S in the OFF state and maintains VCSEL not lit. That is, the lighting signal φI sets the lighting/non-lighting of the VCSEL.

As described above, in the light source device 1 of the present exemplary embodiment, there are a plurality of elements (transfer thyristors T1 to T6, setting thyristors S1 to S6, VCSEL1 to VCSEL6, and the like). Thus, among the plurality of elements, elements to be in the ON state are sequentially turned on. Thereby, in the light source device 1 of the present exemplary embodiment, the plurality of transfer thyristors T1 to T6 in the transfer unit 12 of the light emitting chip 10 are individually turned on by the lighting control by the control unit 110. Then, the transfer thyristors T1 to T6 are turned on. Thus, the VCSELs to be subjected to the lighting control are designated, and the plurality of setting thyristors S1 to S6 in the light emitting unit 11 are individually turned on. Then, in a case where each of the setting thyristors S is turned on, the VCSELs corresponding to the setting thyristors S individually emit light. In addition, in the light source device 1 of the present exemplary embodiment, the control unit 110 and the transfer unit 12 of the light emitting chip 10 each are an example of a driving unit that individually drives a plurality of setting thyristors S to transition to the ON state.

Further, in the light emitting chip 10 of the present exemplary embodiment, a part of the light emission layer 82 of each VCSEL that actually emits light by supplying a current is a light emission region of each VCSEL.

As described above, in the light emitting chip 10 of the present exemplary embodiment, the setting thyristor S is turned on. Therefore, the current can be supplied to the corresponding VCSEL. Then, after that, in a case where a current of a magnitude necessary for light emission of the VCSEL is actually supplied to the VCSEL, the VCSEL emits light.

Meanwhile, according to the configuration of the light emitting chip 10 or the control by the control unit 110, the ON signal to the setting thyristor S may be stopped while the state in which the VCSEL is able to emit light is maintained by supplying a current before the VCSEL emits light after the setting thyristor S is turned on and the current can be supplied to the corresponding VCSEL. Even in such a case, the VCSEL can be made to emit light by supplying the VCSEL with a current having a magnitude necessary for emitting light of the VCSEL after the setting thyristor S is turned off. In addition, in such a case, the setting thyristor S is turned off at a time point at which the VCSEL actually emits light after the setting thyristor S is turned on for emitting light of the VCSEL.

In the present exemplary embodiment, the phrase “the thyristor (setting thyristor S) is turned on to cause the light emitting element (VCSEL) to emit light” means that the setting thyristor S is turned on and the corresponding VCSEL is made capable of emitting light by supplying a current. In addition, the setting thyristor S maintains the ON state or maintains the OFF state at a time point at which the current is supplied to the VCSEL and the VCSEL actually emits light after the VCSEL is made capable of emitting light by supplying a current.

About Light Emitted from Setting Thyristor S

Meanwhile, since the setting thyristor S is constituted of the compound semiconductor as described above, light may be emitted from between the n-gate layer 86 and the p-gate layer 87 in the ON state. In addition, the setting thyristor S may emit light from between the n-gate layer 86 and the p-gate layer 87 in a case where a value of the current flowing between the p-anode layer 85 and the n-cathode layer 88 is large.

In the light source device 1 (light emitting chip 10) in which the plurality of VCSELs and the setting thyristors S are formed on the identical substrate 80, it is considered that the lighting control of the VCSELs may be performed such that one VCSEL selected from the plurality of VCSELs (for example, VCSEL1) is lit and other VCSELs (for example, VCSEL2 to VCSEL6) are lit off. In such a case, the setting thyristor S1 connected to the VCSEL1 to emit light is turned on by the control unit 110, and thereby the VCSEL1 is lit. On the other hand, at a time point at which the setting thyristor S1 is turned on, the other setting thyristors S2 to S6 connected to the other VCSEL2 to VCSEL6 that are not turned on remain in the OFF state.

Then, in a case where the setting thyristor S1 is turned on, light may be emitted from the setting thyristor S1 due to the current which is supplied to the setting thyristor S1.

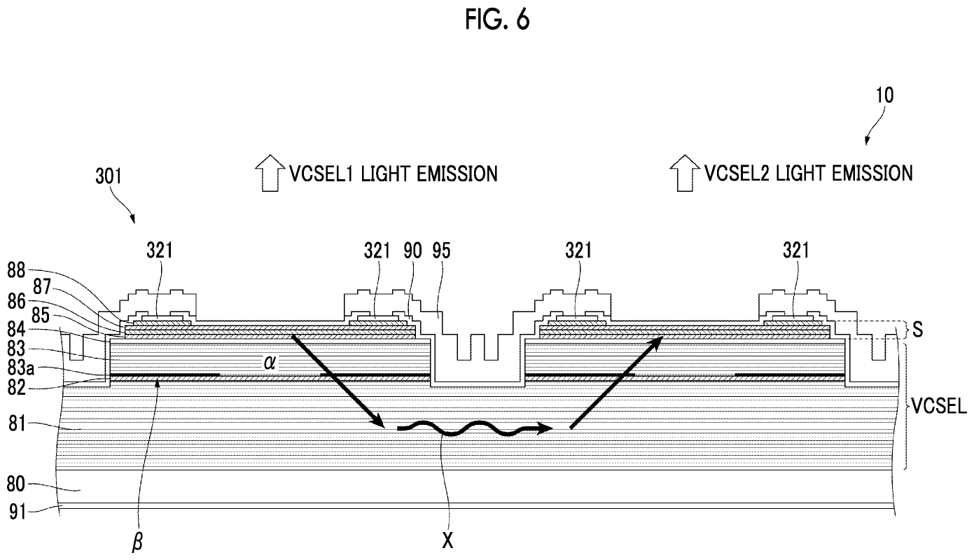

FIG. 6 is a diagram showing an example of the behavior of the light emitted from the setting thyristors S in a case where the VCSELs do not absorb the light emitted from the setting thyristors S. FIG. 6 shows the island 301 in which the VCSEL1 and the setting thyristor S1 are laminated, and the island (unsigned) in which the VCSEL2 and the setting thyristor S2 are laminated, in the same manner as in FIG. 4 described above.

The light emitted from the setting thyristor S1 propagates around the setting thyristor S1 through the inside of each semiconductor layer or the substrate 80 constituting the VCSEL1. Thereby, the light emitted from the setting thyristor S1 may reach another setting thyristor S (for example, the setting thyristor S2) adjacent to the setting thyristor S1. In particular, as described above, in a case where a part of the semiconductor layers constituting the VCSEL are continuous between adjacent VCSELs, the light emitted from the setting thyristor S1 is likely to propagate to the adjacent setting thyristor S2 through the semiconductor layer. In this example, as indicated by an arrow X in FIG. 6, the light emitted from the setting thyristor S1 is likely to propagate to the adjacent setting thyristor S2 through the p-anode (DBR) layer 81 which is mostly continuous with VCSEL1 and VCSEL2.

As described above, in this example, the setting thyristor S2 is turned off in order for the VCSEL2 corresponding to the setting thyristor S2 to be not lit. However, in a case where the light emitted from the setting thyristor S1 propagates to the setting thyristor S2 and is absorbed by the gate layer (n-gate layer 86, p-gate layer 87) of the setting thyristor S2 to generate an electromotive force, the setting thyristor S2 is turned on. Then, as the setting thyristor S2 is turned on, the VCSEL2, which should not be lit originally, emits light.

As described above, in a case where the light emitted from the setting thyristor S is absorbed by another setting thyristor S, the non-lighting VCSEL that is not subjected to the lighting control among the plurality of VCSELs may be erroneously turned on. In such a case, it is difficult to accurately perform lighting control of the plurality of VCSELs in the light source device 1.

On the other hand, in the light emitting chip 10 of the light source device 1 according to the present exemplary embodiment, the VCSEL absorbs the light emitted from the setting thyristors S between the plurality of setting thyristors S. Thus, compared to a case where the VCSEL does not absorb the light emitted from the setting thyristor S, the light emitted from the setting thyristor S is unlikely to propagate to the other setting thyristors S.

Details of Layers Constituting Setting Thyristor S and VCSEL

Subsequently, the layers constituting the setting thyristor S and VCSEL of the light emitting chip 10 according to the present exemplary embodiment will be described in more detail with reference to FIG. 4 and the like.

The VCSEL of the present exemplary embodiment includes the semiconductor layer capable of absorbing the light emitted from the setting thyristor S. Here, in general, the compound semiconductor absorbs light having a wavelength (that is, having a larger band gap energy) shorter than a wavelength corresponding to the band gap energy of the compound semiconductor. Then, in a case where the compound semiconductor absorbs the light, the compound semiconductor emits light corresponding to the band gap energy of the compound semiconductor. Consequently, the light emitted from the setting thyristor S can be absorbed by a semiconductor having a band gap energy smaller than the band gap energy corresponding to the light emitted from the setting thyristor S. The VCSEL of the present exemplary embodiment includes the semiconductor layer formed of a semiconductor in which the band gap energy is smaller than the band gap energy corresponding to the light emitted from the setting thyristor S.

Layer Configuration of Setting Thyristor S

As described above, the setting thyristor S is constituted of the p-anode layer 85, the n-gate layer 86, the p-gate layer 87, and the n-cathode layer 88 which are laminated on the tunnel junction layer 84. As described above, the p-anode layer 85, the n-gate layer 86, the p-gate layer 87, and the n-cathode layer 88 are constituted by the group III-V compound semiconductor.

In the present exemplary embodiment, it is preferable that the n-gate layer 86 and the p-gate layer 87 are constituted by, for example, the group III-V compound semiconductor including Al. Examples of the group III-V compound semiconductor, which includes Al constituting the n-gate layer 86 and the p-gate layer 87, include AlGaAs, AlGaN, and AlAs, and it is preferable to use AlGaAs.

By using the group III-V compound semiconductor, for example, AlGaAs including Al as the n-gate layer 86 and the p-gate layer 87, compared to a case of using a III-V group compound semiconductor, for example, GaAs including no Al as the n-gate layer 86 and the A-gate layer 87, it is possible to increase the band gap energy corresponding to the light emitted from the n-gate layer 86 and the p-gate layer 87. Thereby, the light emitted from the n-gate layer 86 and the p-gate layer 87 is likely to be absorbed by the VCSEL. Further, in a case where the light emitted from the n-gate layer 86 and the p-gate layer 87 is absorbed by the VCSEL or the substrate 80, the light emitted again (re-emitted) from the VCSEL or the substrate 80 is unlikely to be absorbed by the n-gate layer 86 and the p-gate layer 87 of the adjacent setting thyristors S. Thereby, the adjacent setting thyristors S are suppressed from being turned on due to the light re-emission from the VCSEL or the substrate 80.

In a case where the n-gate layer 86 and the p-gate layer 87 are constituted by the group III-V compound semiconductor including Al, for example, the content ratios of Al in the n-gate layer 86 and the p-gate layer 87 are preferably 1% or more, more preferably 7% or more, and yet more preferably 10% or more. In a case where the content ratios of Al in the n-gate layer 86 and the p-gate layer 87 are less than 1%, the light emitted from between the n-gate layer 86 and the p-gate layer 87 is unlikely to be absorbed by the VCSEL, and light may be likely to propagate to the adjacent setting thyristors S.

Further, in the n-gate layer 86 and the p-gate layer 87, the content ratio of Al is, for example, preferably less than 30%, and more preferably less than 20%.

A manufacturing process of the light emitting chip 10 may include a step of exposing the n-gate layer 86 and the p-gate layer 87 to air. In such a case, in a case where the content ratios of Al in the n-gate layer 86 and the p-gate layer 87 are 30% or more, the front surfaces of the n-gate layer 86 and the p-gate layer 87 are likely to be oxidized by air. In such a case, the connection between the n-gate layer 86 and the p-gate layer 87 and the electrodes provided on the layers (for example, the connection between the p-gate layer 87 and the p-ohmic electrode 331) may be poor.

Furthermore, in general, among the semiconductor layers constituting the setting thyristor S, the n-gate layer 86 and the p-gate layer 87 have a lower content ratio of Al than the p-anode layer 85 and the n-cathode layer 88. The driving voltage of the setting thyristor S is determined by the n-gate layer 86 and the p-gate layer 87, which are semiconductor layers in which the content ratio of Al is low among the semiconductor layers constituting the setting thyristor S. In addition, the driving voltage of the setting thyristor S is lower as the content ratios of Al in the n-gate layer 86 and the p-gate layer 87 are lower, and is higher as the content ratios of Al in the n-gate layer 86 and the p-gate layer 87 are higher. Consequently, in a case where the content ratios of Al in the n-gate layer 86 and the p-gate layer 87 are 30% or more, the driving voltage of the setting thyristor S is excessively high, which is not preferable.

As described later, the content ratio of Al of the n-gate layer 86 and the p-gate layer 87 is defined by a relationship between the semiconductor layers that absorb light emitted from the n-gate layer 86 and the p-gate layer 87 provided in the VCSEL, more specifically, the p-anode (DBR) layer 81 and the n-cathode (DBR) layer 83 of the VCSEL.

It should be noted that, in the description of the present exemplary embodiment, a content ratio of Al in the group III-V compound semiconductor including Al means a ratio of the number of atoms of Al to the sum of the number of atoms of the group III elements included in the group III-V compound semiconductor. For example, a content ratio of Al in AlGaAs means a ratio of the number of atoms of Al to the sum of the number of atoms of Al and Ga included in AlGaAs.

As the p-anode layer 85 of the setting thyristor S as described above, for example, the p-type AlGaAs having an impurity concentration of 1×10¹⁸/cm³ can be used. A content ratio of Al in the p-anode layer 85 may be changed between 0% and 100%.

As the n-gate layer 86, for example, the n-type AlGaAs having an impurity concentration of 1×10¹⁷/cm³ can be used. A content ratio of Al in the n-gate layer 86 may be determined in relation to the p-anode (DBR) layer 81 and the n-cathode (DBR) layer 83 of the VCSEL, which will be described later.

As the p-gate layer 87, for example, the p-type AlGaAs having an impurity concentration of 1×10¹⁷/cm³ can be used. A content ratio of Al in the n-gate layer 86 may be determined in relation to the p-anode (DBR) layer 81 and the n-cathode (DBR) layer 83 of the VCSEL, which will be described later.

As the n-cathode layer 88, for example, the n-type AlGaAs having an impurity concentration of 1×10¹⁸/cm³ can be used. A content ratio of Al in the p-anode layer 85 may be changed between 0% and 100%.

Layer Configuration of VCSEL

The VCSEL is constituted by the p-anode (DBR) layer 81, the light emission layer 82, and the n-cathode (DBR) layer 83 laminated on the substrate 80. Then, the VCSEL oscillates the laser by resonating light in the light emission layer 82 interposed between the p-anode (DBR) layer 81 and the n-cathode (DBR) layer 83. The VCSEL oscillates the laser in a case where the reflectance of light by the p-anode (DBR) layer 81 and the n-cathode (DBR) layer 83 is, for example, 99% or more.

The VCSEL of the present exemplary embodiment absorbs the light emitted from the setting thyristors S between the plurality of setting thyristors S. Here, the term “between a plurality of setting thyristors S” means a path until the light emitted from one setting thyristor S among the plurality of setting thyristors S reaches the other setting thyristors S. Consequently, the term “between a plurality of setting thyristors S” includes not only the semiconductor layer of the VCSEL, which is located at the boundary between the adjacent setting thyristors S, but also a semiconductor layer of the VCSEL, to which the light emitted from the setting thyristors S is able to propagate and which is located directly below the setting thyristors S, and the like.

The VCSEL of the present exemplary embodiment includes the semiconductor layer that absorbs light emitted from the n-gate layer 86 and the p-gate layer 87 of the setting thyristor S. In addition, the VCSEL of the present exemplary embodiment includes a semiconductor layer of which the band gap energy is smaller than a band gap energy corresponding to the light which is emitted from the n-gate layer 86 and the p-gate layer 87 of the setting thyristor S.

As described above, the p-anode (DBR) layer 81 and the n-cathode (DBR) layer 83 are DBR layers in which the plurality of semiconductor layers having refractive index differences are laminated.

In addition, the p-anode (DBR) layer 81 has a configuration in which a high refractive index layer that has a relatively high refractive index and a low refractive index layer that has a relatively low refractive index are alternately laminated. It should be noted that the phrase “the high refractive index layer has a relatively high refractive index” means that the refractive index is higher than the refractive index of the low refractive index layer. In a similar manner, the phrase “the low refractive index layer has a relatively low refractive index” means that the refractive index is lower than the refractive index of the high refractive index layer.

Further, in a similar manner to the p-anode (DBR) layer 81, the n-cathode (DBR) layer 83 has a configuration in which a high refractive index layer that has a relatively high refractive index and a low refractive index layer that has a relatively low refractive index are alternately laminated.

In the VCSEL of the present exemplary embodiment, at least one of the high refractive index layer of the p-anode (DBR) layer 81 or the high refractive index layer of the n-cathode (DBR) layer 83 can be used as a semiconductor layer that absorbs the light emitted from the n-gate layer 86 and the p-gate layer 87 of the setting thyristor S. In such a case, in the VCSEL, at least one of the band gap energy of the high refractive index layer of the p-anode (DBR) layer 81 or the band gap energy of the high refractive index layer of the n-cathode (DBR) layer 83 is smaller than a band gap energy corresponding to the light emitted from the n-gate layer 86 and the p-gate layer 87 of the setting thyristor S.

In the present exemplary embodiment, it is preferable that the high refractive index layer of the p-anode (DBR) layer 81 is constituted by, for example, a group III-V compound semiconductor including Al, which is doped with a p-type impurity. In a similar manner, it is preferable that the high refractive index layer of the n-cathode (DBR) layer 83 is constituted by, for example, a group III-V compound semiconductor including Al, which is doped with an n-type impurity.

Examples of the group III-V compound semiconductor constituting the high refractive index layer of the p-anode (DBR) layer 81 and the high refractive index layer of the n-cathode (DBR) layer 83 include AlGaAs, AlGaN, AlAs, and the like, in a similar manner to the n-gate layer 86 and the p-gate layer 87 of the setting thyristor S. Thus, it is preferable to use AlGaAs.

In a case where the high refractive index layer of the p-anode (DBR) layer 81 and the high refractive index layer of the n-cathode (DBR) layer 83 are constituted by the group III-V compound semiconductor including Al, at least one of the high refractive index layer of the p-anode (DBR) layer 81 or the high refractive index layer of the n-cathode (DBR) layer 83 has a content ratio of Al equal to or less than the content ratios of Al in the n-gate layer 86 and the A-gate layer 87 of the setting thyristor S.

In the group III-V compound semiconductor including Al, the band gap energy tends to be larger as the content ratio of Al is higher, and the band gap energy tends to be smaller as the content ratio of Al is lower. Consequently, by making the content ratios of Al in the high refractive index layer of the p-anode (DBR) layer 81 and the high refractive index layer of the n-cathode (DBR) layer 83 smaller than the content ratios of the n-gate layer 86 and the p-gate layer 87, the bandgap energies of the high refractive index layer of the p-anode (DBR) layer 81 and the high refractive index layer of the n-cathode (DBR) layer 83 is smaller than a band gap energy corresponding to the light emitted from the n-gate layer 86 and the p-gate layer 87. Accordingly, the light emitted from the setting thyristor S is absorbed by the high refractive index layer of the p-anode (DBR) layer 81 and the high refractive index layer of the n-cathode (DBR) layer 83 in the VCSEL.

Here, the high refractive index layer and the low refractive index layer of the p-anode (DBR) layer 81 are doped with the p-type impurities from the viewpoint of lowering the electrical resistance and facilitating the flow of the current. From the same viewpoint, the high refractive index layer and the low refractive index layer of the n-cathode (DBR) layer 83 are doped with the n-type impurities. Then, impurity concentrations in the p-anode (DBR) layer 81 and the n-cathode (DBR) layer 83 are higher than impurity concentrations in the n-gate layer 86 and the p-gate layer in the setting thyristor S.

In general, in a compound semiconductor, as the impurity concentration increases, the number of electrons and holes (free carriers) that is able to freely move in the semiconductor increases, and light is likely to be absorbed through absorption of the free carriers. Consequently, in the present exemplary embodiment, the high refractive index layer of the p-anode (DBR) layer 81 and the high refractive index layer of the n-cathode (DBR) layer 83 having high impurity concentrations are able to absorb the light emitted from the n-gate layer 86 and the A-gate layer 87. In such a case, the content ratios of Al in the high refractive index layer of the p-anode (DBR) layer 81 and the high refractive index layer of the n-cathode (DBR) layer 83 may be slightly greater than the content ratios of Al in the n-gate layer 86 and the p-gate layer 87, and may be equal to each other.

From the viewpoint of facilitating absorption of light emitted from the n-gate layer 86 and the p-gate layer 87, the content ratios of Al in the high refractive index layer of the p-anode (DBR) layer 81 and the high refractive index layer of the n-cathode (DBR) layer 83 are, for example, preferably equal to or less than the content ratios of Al in the n-gate layer 86 and the p-gate layer 87, and more preferably less than the content ratios of Al in the n-gate layer 86 and the p-gate layer 87.

In the VCSEL of the present exemplary embodiment, the low refractive index layer of the p-anode (DBR) layer 81 is particularly limited as long as the low refractive index layer is a compound semiconductor that has a lower refractive index than the high refractive index layer and that can be laminated on the high refractive index layer. However, the low refractive index layer is preferably constituted by the group III-V compound semiconductor including Al, which is doped with the p-type impurity. In a similar manner, the low refractive index layer of the n-cathode (DBR) layer 83 is not particularly limited as long as the high refractive index layer is a compound semiconductor that has a lower refractive index than the high refractive index layer and that can be laminated on the high refractive index layer. However, the low refractive index layer is preferably constituted by the group III-V compound semiconductor including Al, which is doped with the n-type impurity.

In a case where the low refractive index layers of the p-anode (DBR) layer 81 and the n-cathode (DBR) layer 83 are formed of the group III-V compound semiconductor including Al, the content ratio of Al is, for example, higher than that in the high refractive index layer, and the content ratio is preferably 30% or less.

A film thickness of each high refractive index layer of the p-anode (DBR) layer 81 is in a range of (λ/4nₚ₁)×0.4 or more and (λ/4nₚ₁)×1.2 or less, and is, for example, preferably λ/4nₚ₁. Here, λ is a wavelength of light emitted from the light emission layer 82 of the VCSEL, and nₚ₁ is a refractive index of the high refractive index layer of the p-anode (DBR) layer 81.

In a similar manner, the film thickness of each high refractive index layer of the n-cathode (DBR) layer 83 is in a range of (λ/4nₙ₁)×0.4 or more and (λ/4nₙ₁)×1.2 or less, and is, for example, preferably λ/4nₙ₁. Here, nₙ₁ is a refractive index of the high refractive index layer of the n-cathode (DBR) layer 83.

It should be noted that the thickness of each high refractive index layer of the p-anode (DBR) layer 81 is, for example, preferably λ/2 which is a total thickness of the high refractive index layers and the low refractive index layers of the p-anode (DBR) layer 81. Consequently, for example, in a case where the film thickness of the high refractive index layer of the p-anode (DBR) layer 81 is thinner than λ/4nₚ₁, the film thickness of the low refractive index layer of the p-anode (DBR) layer 81 may be thicker than λ/4nₚ₂ (nₚ₂ is a refractive index of the low refractive index layer of the p-anode (DBR) layer 81).

In a similar manner, the thickness of each high refractive index layer of the n-cathode (DBR) layer 83 is set to λ/2 which is a total thickness of the high refractive index layers and the low refractive index layers of the n-cathode (DBR) layer 83. Consequently, for example, in a case where the film thickness of the high refractive index layer of the n-cathode (DBR) layer 83 is thinner than λ/4nₙ₁, the film thickness of the low refractive index layer of the n-cathode (DBR) layer 83 may be thicker than λ/4nₙ₂ (nₙ₂ is a refractive index of the low refractive index layer of the n-cathode (DBR) layer 83).

Here, in the VCSEL of the present exemplary embodiment, for example, it is preferable that the p-anode (DBR) layer 81, which is closer to the substrate 80, is more likely to absorb the light emitted from the setting thyristor S than the n-cathode (DBR) layer 83. In addition, in the VCSEL, for example, it is preferable that at least the high refractive index layer of the p-anode (DBR) layer 81 among the p-anode (DBR) layer 81 and the n-cathode (DBR) layer 83 is a semiconductor layer that absorbs the light emitted from the VCSEL.

Here, in a case where the semiconductor layer absorbs light, heat may be generated in accordance therewith. In the present exemplary embodiment, the p-anode (DBR) layer 81 laminated on the substrate 80 absorbs the light emitted from the setting thyristor S. Thereby, heat generated by the absorption of the light is likely to be discharged to the outside of the light emitting chip 10 through the substrate 80. Accordingly, the effect of heat generated by absorbing the light emitted from the setting thyristor S on the light emission layer 82 can be reduced.

Further, in the VCSEL of the present exemplary embodiment, for example, it is preferable that the p-anode (DBR) layer 81 that does not have the current constriction layer is more likely to be absorb the light emitted from the setting thyristor S than the n-cathode (DBR) layer 83 that is provided with the current constriction layer 83a. In addition, in the VCSEL, for example, it is preferable that at least the high refractive index layer of the p-anode (DBR) layer 81 among the p-anode (DBR) layer 81 and the n-cathode (DBR) layer 83 is a semiconductor layer that absorbs the light emitted from the VCSEL.

As described above, the current blocking portion β, in which a current is unlikely to flow, and the current passage portion α, in which a current is likely to flow, are formed on the current constriction layer 83a. Further, in the VCSEL, since the current is concentrated on the current passage portion α, the light emission layer 82 emits light in the vicinity of the current passage portion α.

In the present exemplary embodiment, the p-anode (DBR) layer 81 that does not have the current constriction layer and is separated from the current passage portion α absorbs the light emitted from the setting thyristor S. Thereby, the heat generated by absorbing the light emitted from the setting thyristor S has less effect on the light emission layer 82.

From the viewpoint of absorbing the light emitted from the setting thyristor S at a position away from the current constriction layer, in a case where the p-anode (DBR) layer 81 has the current constriction layer, the n-cathode (DBR) layer may be more likely to absorb the light emitted from the setting thyristor S than the p-anode (DBR) layer 81.

The p-anode (DBR) layer 81 of the VCSEL described above may be, for example, a semiconductor layer in which the low refractive index layers and the high refractive index layers are alternately laminated for 40 cycles. Each of the low refractive index layers is formed of AlGaAs doped with the p-type impurities and Al GaAs doped with the p-type impurities. Each of the high refractive index layers is formed of AlGaAs with a low content ratio of AlGaAs as compared with the low refractive index layer. The content ratio of Al in AlGaAs that constitutes the low refractive index layer of the p-anode (DBR) layer 81 and the content ratio of Al in AlGaAs that constitutes the high refractive index layer thereof may be determined so as to satisfy the above-mentioned conditions.

Further, the n-cathode (DBR) layer 83 may be, for example, a semiconductor layer in which the low refractive index layers and the high refractive index layers are alternately laminated for 19 cycles. Each of the low refractive index layers is formed of AlGaAs doped with the n-type impurities and Al GaAs doped with the n-type impurities. Each of the high refractive index layers is formed of AlGaAs with a low content ratio of AlGaAs as compared with the low refractive index layer. In a similar manner, the content ratio of Al in AlGaAs that constitutes the low refractive index layer of the n-cathode (DBR) layer 83 and the content ratio of Al in AlGaAs that constitutes the high refractive index layer thereof may be determined so as to satisfy the above-mentioned conditions.

Furthermore, the light emission layer 82 may be, for example, a semiconductor layer in which well layers formed of GaN, InGaN, AlGaN, or the like and barrier layers formed of AlGaN, GaN, or the like are alternately laminated.

Configuration of Substrate 80

As described above, the substrate 80 of the present exemplary embodiment is the p-type substrate 80. The substrate 80 is able to employ, for example, a substrate formed of the group III-V compound semiconductor capable of epitaxially growing semiconductor layers such as the p-anode (DBR) layer 81, the light emission layer 82, and the n-cathode (DBR) layer 83 constituting the VCSEL.

In the present exemplary embodiment, for example, the substrate 80 is preferably formed of a semiconductor having the band gap energy smaller than the band gap energy corresponding to the light emitted from the setting thyristor S. More specifically, as the substrate 80, for example, it is more preferable to use a substrate formed of the group III-V compound semiconductor having a small content ratio of Al, and it is more preferable to use the GaAs substrate including no Al, as compared with the high refractive index layer of the p-anode (DBR) layer 81 or the n-cathode (DBR) layer 83 which is a semiconductor layer that absorbs the light emitted from the setting thyristor S.

In the VCSEL, a part of the light emitted from the setting thyristor S and not absorbed by the high refractive index layer of the p-anode (DBR) layer 81 or the n-cathode (DBR) layer 83 may reach the substrate 80. In a case where the substrate 80 is formed of the GaAs substrate, the light emitted from the setting thyristor S is absorbed by the substrate 80, and light having a wavelength corresponding to a band gap energy of GaAs is emitted from the substrate 80. In addition, the light emitted (re-emitted) from the substrate 80 has a wavelength longer than a wavelength corresponding to the band gap energies of the n-gate layer 86 and the p-gate layer 87 of the setting thyristor S.

Consequently, in the present exemplary embodiment, since the substrate 80 is formed of the GaAs substrate, the light re-emitted from the substrate 80 is not absorbed by the n-gate layer 86 and the p-gate layer 87 of the setting thyristor S. Thereby, it is suppressed that the adjacent setting thyristors S are turned on due to the light re-emission from the substrate 80.

Behavior of Light Emitted from Setting Thyristor S

Subsequently, the behavior of the light which is emitted from the setting thyristor S will be described.

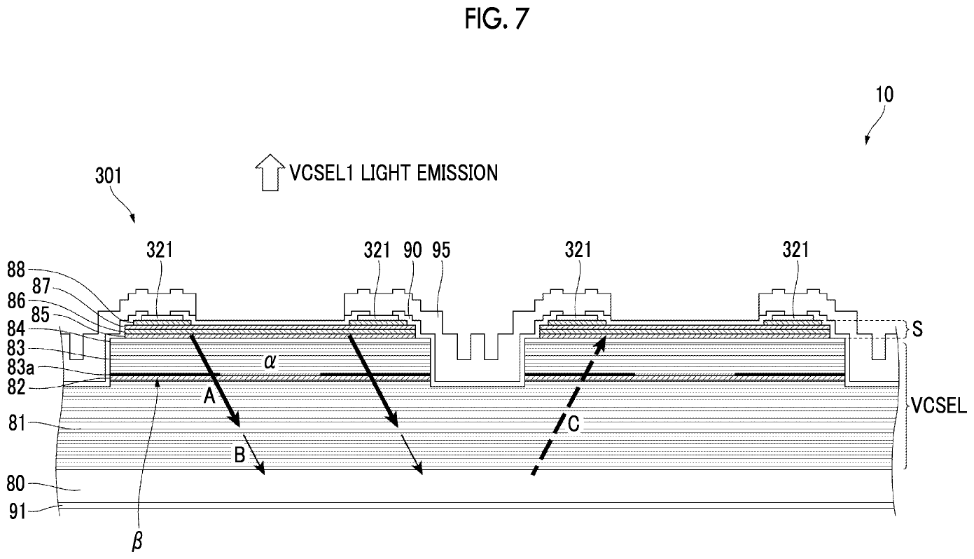

FIG. 7 is a diagram showing an example of the behavior of light emitted from the setting thyristors S in a light emitting chip 10 according to the present exemplary embodiment. FIG. 7 shows the island 301 in which the VCSEL1 and the setting thyristor S1 are laminated, and the island (unsigned) in which the VCSEL2 and the setting thyristor S2 are laminated, in the same manner as in FIG. 4 described above.

Here, in a similar manner to the example shown in FIG. 6, a case where the setting thyristor S1 is turned on and light is emitted from the setting thyristor S1 will be described as an example.

As described above, in the light emitting chip 10 of the present exemplary embodiment, the VCSEL absorbs the light which is emitted from the setting thyristor S1.

Specifically, a part of the light emitted from between the n-gate layer 86 and the p-gate layer 87 of the setting thyristor S1 propagates to the VCSEL1 side which is located below the setting thyristor S1 as indicated by the arrow A in FIG. 7. Then, in a case where the light emitted from the setting thyristor S1 reaches the n-cathode (DBR) layer 83 of the VCSEL1, the high refractive index layer of the n-cathode (DBR) layer 83 absorbs a part of the light. Further, in a case where the light that passes through the n-cathode (DBR) layer 83 of the VCSEL1 without being absorbed reaches the p-anode (DBR) layer 81 of the VCSEL1, the high refractive index layer of the p-anode (DBR) layer 81 absorbs a part of the light.

Further, in the light emitting chip 10 of the present exemplary embodiment, a part of the p-anode (DBR) layer 81 is continuous between the adjacent VCSEL1 and VCSEL2. Then, in a case where the light emitted from the setting thyristor S1 reaches the boundary portion between VCSEL1 and VCSEL2 or the p-anode (DBR) layer 81 of the VCSEL2, the high refractive index layer of the p-anode (DBR) layer 81 absorbs a part of the light.

Further, in a case where the light emitted from the setting thyristor S1 reaches the n-cathode (DBR) layer 83 of the VCSEL2, the high refractive index layer of the n-cathode (DBR) layer 83 absorbs a part of the light.

As indicated by the arrow B in FIG. 7, a part of the light emitted from the setting thyristor S1 may reach the substrate 80 without being not absorbed by the n-cathode (DBR) layer 83 and the p-anode (DBR) layer 81. As described above, the substrate 80 has a band gap energy smaller than a band gap energy corresponding to the light emitted from the setting thyristor S1 such as GaAs. Consequently, the substrate 80 absorbs the light emitted from the setting thyristor S1 and reaching the substrate 80. Then, as indicated by the arrow C in FIG. 7, the light having a long wavelength (light re-emission) corresponding to the band gap energy of the substrate 80 is emitted from the substrate 80.

The light re-emitted from the substrate 80 is smaller than the band gap energies of the n-gate layer 86 and the p-gate layer 87. Therefore, even in a case where the re-emitted light reaches the setting thyristor S2, the re-emitted light is not absorbed by the setting thyristor S2.

As described above, in the light emitting chip 10 of the present exemplary embodiment, the VCSEL absorbs the light emitted from the setting thyristors S between the plurality of setting thyristors S. Therefore, as compared with a case where the VCSEL does not absorb the light emitted from the setting thyristor S, the light emitted from the setting thyristor S is unlikely to propagate to the other setting thyristors S.

Thereby, it is possible to suppress the transition of the other setting thyristors to the ON state, and to suppress the VCSELs that are not intended to emit light from being erroneously lit.

In the present exemplary embodiment, in a case where light is emitted from the setting thyristor S as the thyristor, a case where the VCSEL absorbs the light will be described as an example. Here, as described above, in the light emitting chip 10 of the present exemplary embodiment, the transfer thyristor T also has the same layer configuration as the setting thyristor S. Thus, in a case where the transfer thyristor T is turned on, light may be emitted from between the n-gate layer 86 and the p-gate layer 87 of the transfer thyristor T. In the light emitting chip 10 of the present exemplary embodiment, the VCSEL is able to absorb the light emitted from the transfer thyristor T, as in the above-mentioned example. Thereby, in the light emitting chip 10, the light emitted from the transfer thyristor T is suppressed from propagating to another transfer thyristor T or the setting thyristor S, and the VCSEL that is not intended to be lit is suppressed from being erroneously lit.

Difference between Amounts of Light Received by Adjacent Setting Thyristors S due to Difference between Content Ratios of Al in N-Gate Layer 86 and P-Gate Layer 87 of Setting Thyristors S

Subsequently, in the light emitting chip 10 of the present exemplary embodiment, description will be given of the amount of light emitted from the setting thyristor S (for example, the setting thyristor S1), reaches the adjacent setting thyristor S (for example, the setting thyristor S2), and is received by the adjacent setting thyristor S. Here, description will be given of a difference between the amounts of light received by the setting thyristors S (amounts of received light) in a case where the content ratios of Al in the n-gate layer 86 and the p-gate layer 87 of the setting thyristor S are changed.

Table 1 shows the amount of light received from the setting thyristor S1 in the setting thyristor S2 adjacent to the setting thyristor S1 in a case where the setting thyristor S1 is turned on and the setting thyristor S1 emits light. In addition, Table 1 shows the difference in the amount of light received by the setting thyristor S2 in a case where AlGaAs is used as the n-gate layer 86 and the p-gate layer 87 and the content ratios of Al are different. Table 1 shows the amount of light received by the setting thyristor S2 in a case where the content ratios of Al in the n-gate layer 86 and the p-gate layer 87 are 7% (Configuration Example 2), 10% (Configuration Example 3), and 15% (Configuration Example 4), under assumption that the amount of light received by the setting thyristor S2 is 1 in a case where the content ratios of Al in the n-gate layer 86 and the p-gate layer 87 are 0% (configuration example 1). Further, in the light emitting chip 10 of the configuration examples 1 to 4, the configurations of the setting thyristor S and VCSEL other than the content ratios of Al in the n-gate layer 86 and the p-gate layer 87 are the same as each other.

It should be noted that the amount of light received in Table 1 is obtained by simulation with a computer device.

TABLE 1

| | Content ratio of Al in | Amount of light received |
|---|---|---|
| | n-gate layer/p-gate layer | by setting thyristor S2 |
| Configuration | 0% | 1 |
| Example 1 | | |
| Configuration | 7% | 1/10 |
| Example 2 | | |
| Configuration | 10% | 1/100 |
| Example 3 | | |
| Configuration | 15% | 1/1000 |
| Example 4 | | |

As shown in Table 1, in a case where the content ratios of Al in the n-gate layer 86 and the p-gate layer 87 are in the range of 0% to 15%, it is confirmed that the higher the content ratio of Al, the lower the amount of light received by the setting thyristor S2.

It is presumed that the reason for the above-mentioned result is as follows. That is, the higher the content ratios of Al in the n-gate layer 86 and the p-gate layer 87, the larger the band gap energies of the n-gate layer 86 and the p-gate layer 87. Hence, the higher the content ratios of Al in the n-gate layer 86 and the p-gate layer 87, the smaller the band gap energy of the high refractive index layer of the p-anode (DBR) layer 81 or the n-cathode (DBR) layer 83 in the VCSEL, relative to the band gap energy corresponding to the light emitted from between the n-gate layer 86 and the p-gate layer 87 of the setting thyristor S1. Thereby, as the content ratios of Al in the n-gate layer 86 and the p-gate layer 87 is higher, the light emitted from the setting thyristor S1 is more likely to be absorbed by the high refractive index layer of the p-anode (DBR) layer 81 or the n-cathode (DBR) layer 83 in the VCSEL. As a result, it is presumed that the amount of light received by the setting thyristor S2 is low.

Manufacturing Method of Light Emitting Chip 10

Next, an example of a method for manufacturing the light emitting chip 10 according to the present exemplary embodiment will be described.

The light emitting chip 10 is formed by a semiconductor laminate formation step, an n-ohmic electrode (n-ohmic electrode 321, 323, 324, and the like) formation step, a semiconductor laminate separation step, a current blocking portion β formation step, an etching step, a protective layer 90 formation step, and a wiring and electrode formation step.

In the semiconductor laminate formation step, the p-anode (DBR) layer 81, the light emission layer 82, the n-cathode (DBR) layer 83, the tunnel junction layer 84, the p-anode layer 85, the n-gate layer 86, the p-gate layer 87, and the n-cathode layer 88 is epitaxially grown to form a semiconductor laminate on the substrate 80. The semiconductor layers are laminated by, for example, a metal organic chemical vapor deposition (MOCVD) method, a molecular beam epitaxy (MBE) method, or the like to form a semiconductor laminate.

Here, the p-anode (DBR) layer 81, the light emission layer 82, and the n-cathode (DBR) layer 83 are examples of a first semiconductor laminate that is processed into a light emitting element. Further, the p-anode layer 85, the n-gate layer 86, the p-gate layer 87, and the n-cathode layer 88 provided in the tunnel junction layer 84 are examples of a second semiconductor laminate that is processed into the plurality of thyristors (the setting thyristors S and the transfer thyristors T). The substrate 80 and the semiconductor laminate epitaxially grown on the substrate 80 are examples of a semiconductor-laminated substrate.

Subsequently, in the n-ohmic electrode formation step, first, the n-ohmic electrodes 321, 323, 324 and the like are formed on the n-cathode layer 88.

The n-ohmic electrodes (n-ohmic electrode 321, 323, 324, and the like) are made of, for example, Au (AuGe) including Ge, which is likely to make ohmic contact with an n-type semiconductor layer such as the n-cathode layer 88, and the like.

The n-ohmic electrodes (n-ohmic electrodes 321, 323, 324, and the like) are formed by, for example, a lift-off method.

Subsequently, in the semiconductor laminate separation step, the n-cathode layer 88, the p-gate layer 87, the n-gate layer 86, the p-anode layer 85, the tunnel junction layer 84, the n-cathode (DBR) layer 83, the light emission layer 82, and the p-anode (DBR) layer 81 is sequentially etched and separated into islands such as the islands 301 and 302. The etching may be performed as wet etching using a sulfuric acid-based etching solution (sulfuric acid:hydrogen peroxide solution:water=1:10:300 in weight ratio) or the like, and may be performed as anisotropic dry etching (RIE) using, for example, boron chloride or the like. The etching in the semiconductor laminate separation step may be referred to as mesa etching or post etching.

Subsequently, in the current blocking portion formation step, the current constriction layer 83b of which the side surface is exposed is oxidized from the side surface by the semiconductor laminate separation step to form the current blocking portion β that blocks the current. A remaining portion without being oxidized functions as the current passage portion α.

The oxidation of the current constriction layer 83b is performed by, for example, oxidizing Al of the current constriction layer 83b such as AlGaAs through water vapor oxidation at 300 to 400° C. In such a case, the oxidation proceeds from the exposed side surface, and the current blocking portion β formed by the Al₂O₃ which is an oxide of Al is formed around the islands such as the islands 301 and 302. An unoxidized portion of the current constriction layer 83b functions as the current passage portion α.

In the p-gate layering etching step, the n-cathode layer 88 is etched such that the p-gate layer 87 is exposed.

The etching may be performed as wet etching using a sulfuric acid-based etching solution (sulfuric acid:hydrogen peroxide solution:water=1:10:300 in weight ratio), and may be performed as anisotropic dry etching using, for example, boron chloride.

In the p-ohmic electrode formation step, the p-ohmic electrodes 331, 332 and the like are formed on the p-gate layer 87.

The p-ohmic electrodes (p-ohmic electrodes 331, 332, and the like) are made of, for example, Au (AuZn) including Zn, which is likely to make ohmic contact with a p-type semiconductor layer such as the p-gate layer 87, and the like.

The p-ohmic electrodes (p-ohmic electrodes 331, 332, and the like) are formed by, for example, the lift-off method.

In the protective layer formation step, the protective layer 90 is formed to cover the front surfaces of the islands 301 and 302 with an insulating material such as SiO₂, SiON, or SiN.

Further, a through-hole (opening) is provided in the protective layer 90 on the n-ohmic electrodes (n-ohmic electrodes 321, 323, and 324 and the like) and the p-ohmic electrodes (p-ohmic electrodes 331 and 332 and the like).

In the wiring formation step or the like, wiring (the power source line 71, the first transfer signal line 72, the second transfer signal line 73, the lighting signal line 75, and the like) for connecting the n-ohmic electrodes (n-ohmic electrodes 321 or 323, 324, and the like) and the p-ohmic electrodes (p-ohmic electrodes 331, 332, and the like) through the through-hole provided in the protective layer 90, the rear surface electrode 91, and the light blocking layer 95 are formed.

The wiring, the rear surface electrode 91, and the light blocking layer 95 are made of Au, Al, or the like.

Through the above-mentioned steps, the light emitting chip 10 of the present exemplary embodiment is obtained.

It should be noted that, in the light emitting chip 10 of the present exemplary embodiment, the VCSELs and the setting thyristors S are laminated. Thereby, the light emitting chip 10 is formed as a self-scanning type which individually lights the VCSELs through the transfer thyristors T and the setting thyristors S. Accordingly, the number of terminals provided on the light emitting chip 10 is reduced, and the size of the light emitting chip 10 and the light source device 1 is reduced.

### Exemplary Embodiment 2

In the above description of the example of the light emitting chip 10 of Exemplary Embodiment 1, the VCSEL includes a p-anode (DBR) layer 81, a light emission layer 82, and an n-cathode (DBR) layer 83, and is absorbed by the p-anode (DBR) layer 81 or the n-cathode (DBR) layer 83. The light emitting chip 10 of Exemplary Embodiment 2 is different from the light emitting chip 10 of Exemplary Embodiment 1 in that the VCSEL includes the absorptive layer 89 capable of absorbing the light emitted from the setting thyristor S in addition to the p-anode (DBR) layer 81, the light emission layer 82, and the n-cathode (DBR) layer 83.

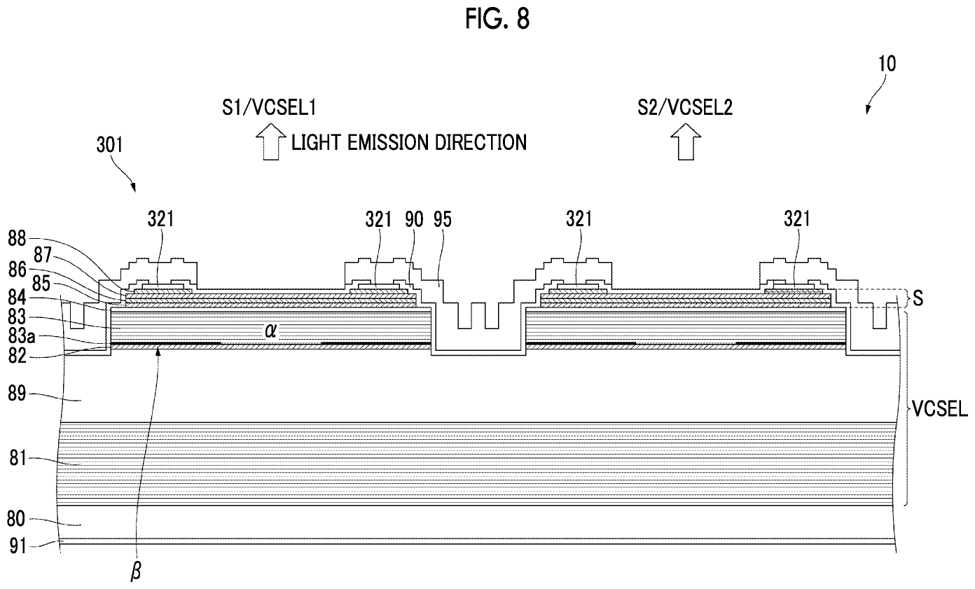

FIG. 8 is a diagram showing the light emitting chip 10 according to Exemplary Embodiment 2, and is an example of an enlarged cross-sectional view of an island in which the VCSEL and the setting thyristor S are laminated. FIG. 8 shows the island 301 in which the VCSEL1 and the setting thyristor S1 are laminated, and the island (unsigned) in which the VCSEL2 and the setting thyristor S2 are laminated, in the same manner as in FIG. 4 described above. It should be noted that, in FIG. 8, the same reference numerals are used for the same configurations as the light emitting chip 10 of Exemplary Embodiment 1 shown in FIG. 4 and the like, and detailed description thereof will be omitted here.

As shown in FIG. 8, in the light emitting chip 10 of Exemplary Embodiment 2, the VCSEL includes the absorptive layer 89 which is able to absorb the light emitted from the setting thyristor S between the p-anode (DBR) layer 81 and the light emission layer 82.

In the VCSEL of Exemplary Embodiment 2, a part of the absorptive layer 89 is continuous with the adjacent VCSEL, similarly to the p-anode (DBR) layer 81.

A material of the absorptive layer 89 is not particularly limited as long as the absorptive layer 89 is lattice-matched to the substrate 80 and is able to absorb the light emitted from the setting thyristor S.

Further, the absorption of the light emitted from the setting thyristor S by the absorptive layer 89 may be band end absorption due to a difference in band gap energy between the light emitted from the setting thyristor S and the absorptive layer 89, and may be free carrier absorption due to impurities and the like included in the absorptive layer 89.

As the absorptive layer 89, for example, the group III-V compound semiconductor can be used. As the absorptive layer 89, the group III-V compound semiconductor including Al such as AlGaAs, AlGaN, and AlAs can be used, similarly to the p-anode (DBR) layer 81 and the n-cathode (DBR) layer 83. Further, as the absorptive layer 89, an Al-free group III-V compound semiconductor such as GaInP, GaInAs, GaInNAs, or the like may be used.

Further, the absorptive layer 89 may be doped with an impurity in order to facilitate absorption of the light emitted from the setting thyristor S.

Furthermore, the absorptive layer 89 may be constituted of a single layer formed of one type compound semiconductor, or may be constituted of a plurality of layers formed of different compound semiconductors.

A thickness of the absorptive layer 89 of the present exemplary embodiment is, for example, preferably thicker than a wavelength of the light emitted from the setting thyristor S. In a case where the film thickness of the absorptive layer 89 is greater than the wavelength of the light emitted from the setting thyristor S, the light emitted from the setting thyristor S is likely to be absorbed through the free carrier absorption.

In the light emitting chip 10 shown in FIG. 8, the absorptive layer 89 is provided between the p-anode (DBR) layer 81 of the VCSEL and the light emission layer 82, but the present invention is not limited thereto. For example, the absorptive layer 89 may be provided between the light emission layer 82 of the VCSEL and the n-cathode (DBR) layer 83, and may be provided both between the p-anode (DBR) layer 81 and the light emission layer 82 and between the light emission layer 82 and the n-cathode (DBR) layer 83.

Although the exemplary embodiments of the present invention have been described above, the technical scope of the present invention is not limited to the above exemplary embodiment.

For example, in the description of the example of the light source device 1 of the above-mentioned exemplary embodiment, the control unit 110 and the transfer unit 12 of the light emitting chip 10 serve as a driving unit that individually drives the setting thyristor S to transition to the ON state. However, a signal may be directly transmitted from the control unit 110 to the setting thyristor S to individually drive the setting thyristor S2.

In addition, various modifications and alternative configurations are involved in the present invention without departing from the technical scope of the present invention.

Supplementary Note

(((1)))

A light emitting component comprising:
a substrate;
a plurality of light emitting elements that are provided on the substrate and respectively have light emission regions; and
a plurality of thyristors that are turned on to cause the light emission regions of the respective light emitting elements to emit light, or that increase amounts of emitted light of the light emission regions,
wherein the light emitting elements absorb light emitted from a corresponding thyristor among the plurality of thyristors.

(((2)))

The light emitting component according to (((1))),
wherein the light emitting elements have a semiconductor layer having a band gap energy smaller than a band gap energy corresponding to light emitted from the thyristors.

(((3)))

The light emitting component according to (((2))),
wherein the thyristors include a gate layer formed of a semiconductor including Al, and
wherein the semiconductor layer of the light emitting elements includes Al and a content ratio of Al of the semiconductor layer is equal to or less than a content ratio of Al of the gate layer.

(((4)))

The light emitting component according to (((3))),
wherein the gate layer of the thyristors has a content ratio of Al of less than 30%.

(((5)))

The light emitting component according to according to any one of (((2))) to (((4))),
wherein assuming that λ is an emission wavelength due to the light emission regions and n is a refractive index of the semiconductor layer, the semiconductor layer of the light emitting elements has a thickness of (λ/4n)×0.4 or more and (λ/4n)×1.2 or less.

(((6)))

The light emitting component according to any one of (((1))) to (((5))),
wherein the plurality of thyristors are laminated on a side opposite to the substrate with respect to the plurality of light emitting elements.

(((7)))

The light emitting component according to (((6))),
wherein the light emitting elements each have a first region corresponding to one thyristor among the plurality of thyristors and a second region corresponding to another thyristor adjacent to the one thyristor, and at least a part of the first region or the second region is continuous.

(((8)))

The light emitting component according to (((7))),
wherein the light emitting element includes a lower semiconductor layer laminated on the substrate and continuous over the first region and the second region, and an upper semiconductor layer laminated on the lower semiconductor layer and divided between the first region and the second region.

(((9)))

The light emitting component according to (((6))),
wherein the light emitting elements each have a lower semiconductor layer laminated on the substrate, a light emission layer laminated on the lower semiconductor layer, and an upper semiconductor layer laminated on the light emission layer, and the lower semiconductor layer is likely to absorb the light emitted from the thyristors than the upper semiconductor layer.

(((10)))

The light emitting component according to any one of (((1))) to (((9))),
wherein the light emitting elements each have a film thickness greater than an emission wavelength and include an absorptive layer that absorbs light emitted from the thyristors.

(((11)))

The light emitting component according to (((10))),
wherein the light emitting elements each includes a lower semiconductor layer laminated on the substrate, a light emission layer laminated on the lower semiconductor layer, and an upper semiconductor layer laminated on the light emission layer, and the absorptive layer is provided between the lower semiconductor layer and the upper semiconductor layer.

(((12)))

A semiconductor-laminated substrate comprising:
a substrate;
a first semiconductor laminate that is provided on the substrate and processed into light emitting elements; and
a second semiconductor laminate that is laminated on the first semiconductor laminate, includes a gate layer, and is processed into a plurality of thyristors,
wherein the first semiconductor laminate includes a semiconductor layer having a band gap energy smaller than a band gap energy of the gate layer of the second semiconductor laminate.

(((13)))

A light emitting device comprising:
a substrate;
a plurality of light emitting elements that are provided on the substrate and respectively have light emission regions;
a plurality of thyristors that are turned to cause the light emission regions of the respective light emitting elements to emit light, or that increase amounts of emitted light of the light emission regions; and
a driving unit that individually drives the plurality of thyristors such that the thyristors transition to an ON state,
wherein the light emitting elements absorb light emitted from a corresponding thyristor among the plurality of thyristors.

(((14)))

A measurement apparatus comprising:
a substrate;
a plurality of light emitting elements that are provided on the substrate and respectively have light emission regions;
a plurality of thyristors that are turned to cause the light emission regions of the respective light emitting elements to emit light, or that increase amounts of emitted light of the light emission regions;
a driving unit that individually drives a plurality of thyristors and causes each of the light emission regions to emit light at a predetermined timing; and
an acquisition unit that acquires information about a target object on the basis of reflected light which is reflected by the target object from each of the light emission regions,
wherein the light emitting elements absorb light emitted from a corresponding thyristor among the plurality of thyristors.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting component comprising:
a substrate;
a plurality of light emitting elements that are provided on the substrate and respectively have light emission regions; and
a plurality of thyristors that are turned on to cause the light emission regions of the respective light emitting elements to emit light, or that increase amounts of emitted light of the light emission regions,
wherein the light emitting elements absorb light emitted from a corresponding thyristor among the plurality of thyristors.

2. The light emitting component according to claim 1,
wherein the light emitting elements have a semiconductor layer having a band gap energy smaller than a band gap energy corresponding to light emitted from the thyristors.

3. The light emitting component according to claim 2,
wherein the thyristors include a gate layer formed of a semiconductor including Al, and
wherein the semiconductor layer of the light emitting elements includes Al and a content ratio of Al of the semiconductor layer is equal to or less than a content ratio of Al of the gate layer.

4. The light emitting component according to claim 3,
wherein the gate layer of the thyristors has a content ratio of Al of less than 30%.

5. The light emitting component according to claim 2,
wherein assuming that λ is an emission wavelength due to the light emission regions and n is a refractive index of the semiconductor layer, the semiconductor layer of the light emitting elements has a thickness of (λ/4n)×0.4 or more and (λ/4n)×1.2 or less.

6. The light emitting component according to claim 3,
wherein assuming that λ is an emission wavelength due to the light emission regions and n is a refractive index of the semiconductor layer, the semiconductor layer of the light emitting elements has a thickness of (λ/4n)×0.4 or more and (λ/4n)×1.2 or less.

7. The light emitting component according to claim 4,
wherein assuming that λ is an emission wavelength due to the light emission regions and n is a refractive index of the semiconductor layer, the semiconductor layer of the light emitting elements has a thickness of (λ/4n)×0.4 or more and (λ/4n)×1.2 or less.

8. The light emitting component according to claim 1,
wherein the plurality of thyristors are laminated on a side opposite to the substrate with respect to the plurality of light emitting elements.

9. The light emitting component according to claim 8,
wherein the light emitting elements each have a first region corresponding to one thyristor among the plurality of thyristors and a second region corresponding to another thyristor adjacent to the one thyristor, and at least a part of the first region or the second region is continuous.

10. The light emitting component according to claim 8,
wherein the light emitting elements each have a lower semiconductor layer laminated on the substrate, a light emission layer laminated on the lower semiconductor layer, and an upper semiconductor layer laminated on the light emission layer, and the lower semiconductor layer is likely to absorb the light emitted from the thyristors than the upper semiconductor layer.

11. The light emitting component according to claim 1,
wherein the light emitting elements each have a film thickness greater than an emission wavelength and include an absorptive layer that absorbs light emitted from the thyristors.

12. A semiconductor-laminated substrate comprising:
a substrate;
a first semiconductor laminate that is provided on the substrate and processed into light emitting elements; and
a second semiconductor laminate that is laminated on the first semiconductor laminate, includes a gate layer, and is processed into a plurality of thyristors,
wherein the first semiconductor laminate includes a semiconductor layer having a band gap energy smaller than a band gap energy of the gate layer of the second semiconductor laminate.

13. A measurement apparatus comprising:
a substrate;
a plurality of light emitting elements that are provided on the substrate and respectively have light emission regions;
a plurality of thyristors that are turned to cause the light emission regions of the respective light emitting elements to emit light, or that increase amounts of emitted light of the light emission regions;
a driving unit that individually drives a plurality of thyristors and causes each of the light emission regions to emit light at a predetermined timing; and
an acquisition unit that acquires information about a target object on the basis of reflected light which is reflected by the target object from each of the light emission regions,
wherein the light emitting elements absorb light emitted from a corresponding thyristor among the plurality of thyristors.
